(19) United States
(12) Patent Application Publication
(10) Pub. No.: US 2024/0404948 A1
(43) Pub. Date: Dec. 5, 2024

(54) SEMICONDUCTOR MEMORY DEVICE

(71) Applicant: Kioxia Corporation, Tokyo (JP)

(72) Inventor: Daisuke KAWAMURA, Kiyosu (JP)

(73) Assignee: Kioxia Corporation, Tokyo (JP)

(21) Appl. No.: 18/680,509

(22) Filed: May 31, 2024

(30) Foreign Application Priority Data
Jun. 2, 2023 (JP) 2023-091623

(51) Int. Cl. H01L 23/528; H10B 41/10; H10B 41/27; H10B 43/10; H10B 43/27

(52) U.S. Cl. CPC H01L 23/5283; H01L 23/528; H10B 41/10; H10B 41/27; H10B 43/10; H10B 43/27

(57) ABSTRACT

A semiconductor memory device of an embodiment includes: a stacked body including conductive layers stacked apart from each other and having a step portion where the conductive layers are processed in a step-like shape; contacts arranged in the step portion at least on one line in a first direction intersecting with a stacking direction of the stacked body and respectively connected with the conductive layers. A plurality of columnar portions includes first columnar portions having a layer structure different from that of a pillar, and second columnar portions having a same layer structure as that of the pillar. The first columnar portions are arranged on an array at least partially overlapping an array position of the contacts in the first direction. The second columnar portions are arranged on an array away from the array position of the contacts in a second direction intersecting with the stacking direction and the first direction.

### CROSS-REFERENCE TO RELATED APPLICATIONS

This application is based upon and claims the benefit of priority from Japanese Patent Application No. 2023-091623, filed on Jun. 2, 2023; the entire contents of which are incorporated herein by reference.

### FIELD

Embodiments described herein relate generally to a semiconductor memory device.

### BACKGROUND

In a semiconductor memory device such as a three-dimensional nonvolatile memory, memory cells are three-dimensionally arranged in a stacked body in which a plurality of conductive layers is stacked to be separated from each other. However, in a partial region, the stacked body subducts in a stacking direction, and thus unevenness may occur on the top surface of the stacked body.

### BRIEF DESCRIPTION OF THE DRAWING

FIGS. 1A and 1B are diagrams illustrating a schematic configuration example of a semiconductor memory device according to a first embodiment;

FIGS. 2A to 2D are cross-sectional views extending along a Y direction that illustrate an example of a configuration of the semiconductor memory device according to the first embodiment;

FIGS. 3A to 3C are cross-sectional views extending along the Y direction that illustrate an example of a configuration of the semiconductor memory device according to the first embodiment;

FIGS. 4A to 4C are cross-sectional views extending along the Y direction that illustrate an example of a configuration of the semiconductor memory device according to the first embodiment;

FIGS. 5A and 5B are XY cross-sectional views at an arbitrary height position in an insulating layer covering a step portion that illustrate an arrangement example of columnar portions according to the first embodiment;

FIGS. 6A to 6C are XY cross-sectional views at an arbitrary height position in the insulating layer covering the step portion that illustrate an arrangement example of the columnar portions according to the first embodiment;

FIG. 7 is a schematic diagram illustrating one of application examples in a case where the columnar portions are arranged on the basis of a prescription in the semiconductor memory device according to the first embodiment;

FIGS. 8A to 8E are diagrams sequentially exemplifying a part of procedures of a manufacturing method of the semiconductor memory device according to the first embodiment;

FIGS. 9A to 9C are diagrams sequentially exemplifying a part of procedures of the manufacturing method of the semiconductor memory device according to the first embodiment;

FIGS. 10A and 10B are diagrams sequentially exemplifying a part of procedures of the manufacturing method of the semiconductor memory device according to the first embodiment;

FIGS. 11A and 11B are diagrams sequentially exemplifying a part of procedures of the manufacturing method of the semiconductor memory device according to the first embodiment;

FIGS. 12A and 12B are diagrams sequentially exemplifying a part of procedures of the manufacturing method of the semiconductor memory device according to the first embodiment;

FIGS. 13A and 13B are diagrams sequentially exemplifying a part of procedures of the manufacturing method of the semiconductor memory device according to the first embodiment;

FIGS. 14A and 14B are diagrams sequentially exemplifying a part of procedures of the manufacturing method of the semiconductor memory device according to the first embodiment;

FIGS. 15A and 15B are diagrams sequentially exemplifying a part of procedures of the manufacturing method of the semiconductor memory device according to the first embodiment;

FIGS. 16A and 16B are diagrams sequentially exemplifying a part of procedures of the manufacturing method of the semiconductor memory device according to the first embodiment;

FIGS. 17A and 17B are diagrams sequentially exemplifying a part of procedures of the manufacturing method of the semiconductor memory device according to the first embodiment;

FIGS. 18A and 18B are diagrams sequentially exemplifying a part of procedures of the manufacturing method of the semiconductor memory device according to the first embodiment;

FIGS. 19A to 19D are diagrams sequentially exemplifying a part of procedures of the manufacturing method of the semiconductor memory device according to the first embodiment;

FIGS. 20A to 20C are diagrams sequentially exemplifying a part of procedures of the manufacturing method of the semiconductor memory device according to the first embodiment;

FIG. 21 is a schematic plan view illustrating a layout of a semiconductor memory device according to a modified example of the first embodiment;

FIGS. 22A and 22B are diagrams illustrating a schematic configuration example of a semiconductor memory device according to a second embodiment;

FIG. 23 is a cross-sectional view extending along the Y direction that illustrates an example of a configuration of a step region included in the semiconductor memory device according to the second embodiment; and

FIG. 24 is a schematic diagram illustrating one of application examples in a case where columnar portions are arranged on the basis of a prescription in the semiconductor memory device according to the second embodiment.

### DETAILED DESCRIPTION

In general, according to one embodiment, a semiconductor memory device includes a stacked body, a plurality of contacts, a pillar, and a plurality of columnar portions. The stacked body includes a plurality of conductive layers stacked apart from each other, and has a step portion where the plurality of conductive layers is processed in a step-like shape. The plurality of contacts is arranged in the step portion at least on one line in a first direction intersecting with a stacking direction of the stacked body, and respectively connected with the plurality of conductive layers. The pillar extends in the stacking direction in the stacked body deviated from the step portion, and forms a memory cell at a respective intersection with at least a part of the plurality of conductive layers. The plurality of columnar portions is arranged in the step portion to form a plurality of arrays each extending in the first direction, and extends in the stacking direction. The plurality of columnar portions includes: a plurality of first columnar portions including a first insulating layer and having a layer structure different from that of the pillar, and a plurality of second columnar portions having a same layer structure as that of the pillar. A first group including at least a part of the plurality of first columnar portions is arranged on an array at least partially overlapping an array position of the plurality of contacts in the first direction, among the plurality of arrays. A second group including at least a part of the plurality of second columnar portions is arranged on an array away from the array position of the plurality of contacts in a second direction intersecting with the stacking direction and the first direction, among the plurality of arrays.

Exemplary embodiments of the present invention will be explained below in detail with reference to the accompanying drawings. In addition, the present invention is not limited to the following embodiments. Further, components in the following embodiments include components that can be easily conceived by the one skilled in the art, or substantially the same components.

### First Embodiment

Hereinafter, the first embodiment will be described in detail with reference to the drawings.

### (Configuration Example of Semiconductor Memory Device)

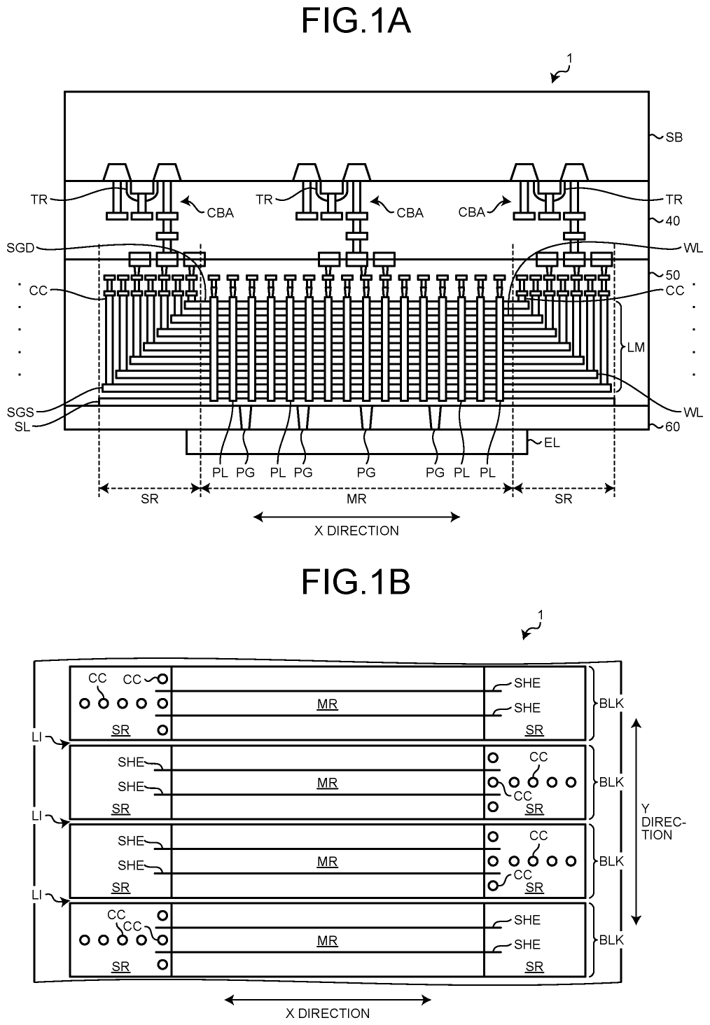

FIGS. 1A and 1B are diagrams illustrating a schematic configuration example of a semiconductor memory device 1 according to the first embodiment. More specifically, FIG. 1A is a cross-sectional view extending along an X direction that illustrates the semiconductor memory device 1, and FIG. 1B is a schematic plan view illustrating the layout of the semiconductor memory device 1.

Note that hatching is omitted in FIG. 1A in consideration of visibility of the drawing. Further, in FIG. 1A, components that do not always exist on the same cross section are illustrated, and moreover, some upper layer wires and the like are omitted.

Further, in this specification, both of the X direction and a Y direction are directions extending along the direction of the surface of a word line WL, and the X direction and the Y direction are orthogonal to each other. Further, an electric drawing direction of the word line WL will be sometimes referred to as a first direction, and this first direction is a direction along the X direction. Further, a direction intersecting with the first direction will be sometimes referred to as a second direction, and this second direction is a direction along the Y direction. Note that the first direction and the second direction are not always orthogonal to each other because the semiconductor memory device 1 can include a manufacturing variation.

As illustrated in FIG. 1A, the semiconductor memory device 1 includes, in order from a lower side of the paper, an electrode film EL, a source line SL, one or more selection gate lines SGS, a plurality of word lines WL, one or more selection gate lines SGD, and a semiconductor substrate SB provided with a peripheral circuit CBA.

The source line SL is arranged on the electrode film EL via an insulating layer 60. A plurality of plugs PG is arranged in the insulating layer 60, and the source line SL and the electrode film EL keep electric conduction via the plugs PG. An electrode pad (not illustrated) for supplying power and signals to the semiconductor memory device 1 from the outside is provided on the same layer of the electrode film EL. The selection gate lines SGS, the plurality of word lines WL, and the selection gate lines SGD are stacked in this order above the source line SL, and a stacked body LM is thereby formed.

As illustrated in FIGS. 1A and 1B, a memory region MR is arranged at the central portion in the X direction of the plurality of word lines WL, and step regions SR are respectively arranged at the both ends in the X direction of the plurality of word lines WL. The memory region MR and the step regions SR are divided into a plurality of regions by a plurality of plate-like contacts LI penetrating through the plurality of word lines WL and the like, and extending in a direction along the X direction.

In addition, a region that is arranged between the plate-like contacts LI neighboring in the Y direction, and includes the memory region MR and the step regions SR will be referred to as a block region BLK. As described later, the memory region MR includes a plurality of memory cells holding data in a nonvolatile manner, and the above-described block region BLK is an erasing unit of these pieces of data.

Further, a plurality of separating layers SHE penetrating through the selection gate lines SGD and extending in a direction along the X direction is arranged between the plate-like contacts LI neighboring in the Y direction. The plurality of separating layers SHE extends in the direction along the X direction, over the entire memory region MR, and reaches a part of the step regions SR at both ends in the X direction.

A plurality of pillars PL penetrating through the word lines WL and the selection gate lines SGD and SGS in the stacking direction is arranged in the memory region MR. Lower ends of the pillars PL reach the source line SL. The plurality of memory cells is formed at intersections between the pillar PL and the word lines WL. The semiconductor memory device 1 is thereby formed as a three-dimensional nonvolatile memory in which memory cells are three-dimensionally arranged in the memory region MR, for example.

In the step regions SR, the plurality of word lines WL and the selection gate lines SGD and SGS are terminated with being processed in a step-like shape. At this time, because the plurality of word lines WL and the selection gate lines SGD and SGS constituting a terrace portion shift from an upper layer side to a lower layer side as getting away from the memory region MR in the X direction, a height position of the terrace portion declines toward the source line SL side.

In addition, the above-described separating layers SHE extend from the memory region MR up to the portions of the step regions SR in which the selection gate lines SGD are processed in a step-like shape. The selection gate lines SGD are thereby separated into a plurality of regions within one block region BLK. In other words, by the separating layers SHE penetrating through upper layer portions existing superior to the plurality of word lines WL, these upper layer portions are segmented into patterns of the plurality of selection gate lines SGD.

In the terrace portion on each step formed by the plurality of word lines WL and the selection gate lines SGD and SGS, a contact CC connected to the word lines WL and the selection gate lines SGD and SGS in each layer is individually arranged. In the word lines WL and the selection gate line SGS, one contact CC is connected for one layer. In the selection gate lines SGD, for one layer, one contact CC is connected for each section separated by the separating layers SHE.

Here, in one block region BLK, the plurality of contacts CC is arranged on one side of the step regions SR that are arranged on both sides of the X direction. Further, when viewed on one side in the X direction, for example, the plurality of contacts CC is arranged for every two block regions BLK.

That is, in the example in FIG. 1B, among the step regions SR at both ends of the X direction, in the block region BLK in the uppermost part of the paper, the plurality of contacts CC is arranged in the step region SR on the left side of the paper. Further, in the block region BLK existing immediately below the above-described block region BLK, and the block region BLK existing further below the block region BLK, the plurality of contacts CC is arranged in the step region SR on the right side of the paper among the step regions SR at the X direction both ends. Furthermore, in the block region BLK in the lowermost part of the paper, the plurality of contacts CC is arranged again in the step region SR on the left side of the paper.

Accordingly, the contacts CC in the step regions SR at the X direction both ends that are illustrated in FIG. 1A belong to different block regions BLK, and are not actually positioned in the same cross section.

The word lines WL and the like stacked in a multilayered manner are individually drawn by these contact CC. More specifically, a writing voltage, a readout voltage, and the like are applied to memory cells included in the memory region MR at the central portion of the plurality of word lines WL, from these contacts CC, via the word lines WL at the same height position as the memory cells.

The plurality of word lines WL and the selection gate lines SGD and SGS, the pillars PL, and the contacts CC are covered with an insulating layer 50. The insulating layer 50 extends also up to the periphery of these components.

The semiconductor substrate SB existing above the insulating layer 50 is a silicon substrate or the like, for example. The peripheral circuit CBA including a transistor TR, a wire, and the like is arranged on the surface of the semiconductor substrate SB. Various voltages applied from the contacts CC to memory cells are controlled by the peripheral circuit CBA electrically connected with these contacts CC. The peripheral circuit CBA thereby controls electrical operations of the memory cells.

The peripheral circuit CBA is covered with an insulating layer 40, and by bonding the insulating layer 40 and the insulating layer 50 covering the plurality of word lines WL and the like, the semiconductor memory device 1 is formed to include components such as the plurality of word lines WL and the selection gate lines SGD and SGS, the pillars PL, the contacts CC, and the like, and the peripheral circuit CBA.

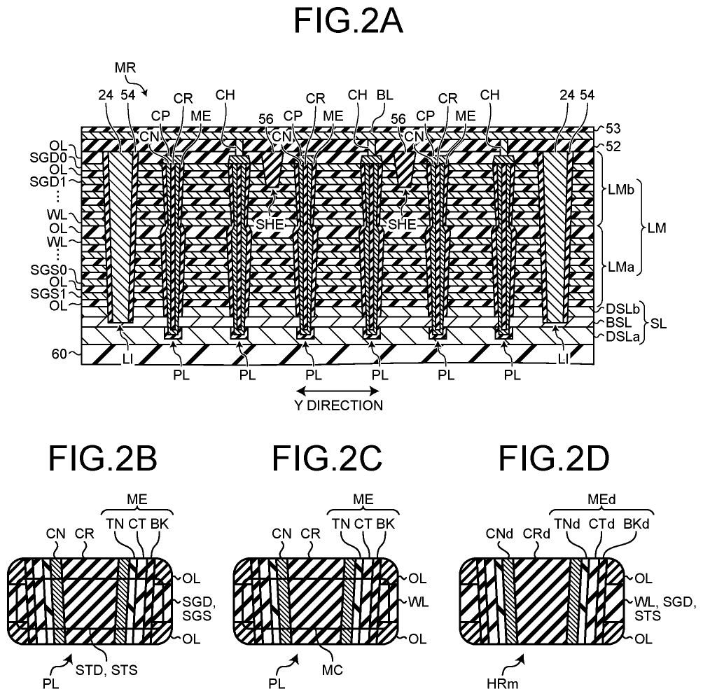

Next, a detailed configuration example of the semiconductor memory device 1 will be described with reference to FIGS. 2A to 4C. FIGS. 2A to 4C are cross-sectional views extending along the Y direction that illustrate an example of a configuration of the semiconductor memory device 1 according to the first embodiment.

More specifically, FIG. 2A is a cross-sectional view of the semiconductor memory device 1 in the memory region MR. In FIG. 2A, a structure existing below the insulating layer 60 and a structure existing above an insulating layer 53 to be described later are omitted.

FIG. 2B is an enlarged cross-sectional view of the pillar PL at a height position of the selection gate lines SGD and SGS. FIG. 2C is an enlarged cross-sectional view of the pillar PL at a height position of the word line WL. FIG. 2D is an enlarged cross-sectional view of a columnar portion HRm at a height position of the word line WL or the selection gate lines SGD or SGS.

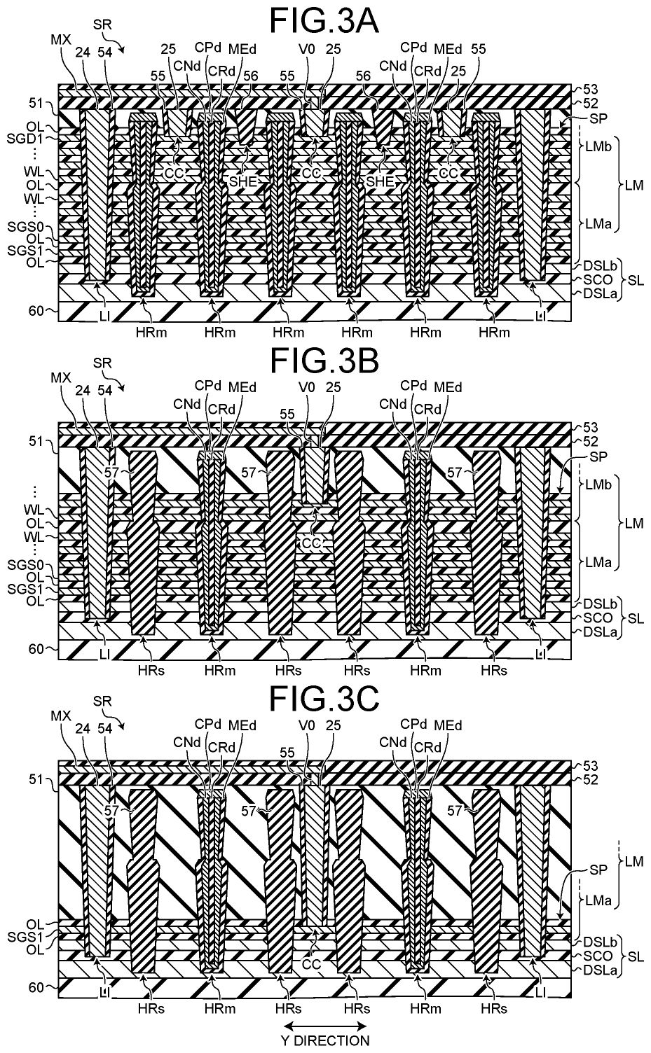

FIGS. 3A to 3C are cross-sectional views of a portion of the step region SR in which the plurality of contacts CC is arranged, FIG. 3A illustrates a cross section of a portion in which the selection gate line SGD is made stepped, FIG. 3B illustrates a cross section of a portion in which arbitrary word line WL is made stepped, and FIG. 3C illustrates a cross section of a portion in which the selection gate line SGS is made stepped. In FIGS. 3A to 3C, the structure existing below the insulating layer 60 and the structure existing above the insulating layer 53 are omitted.

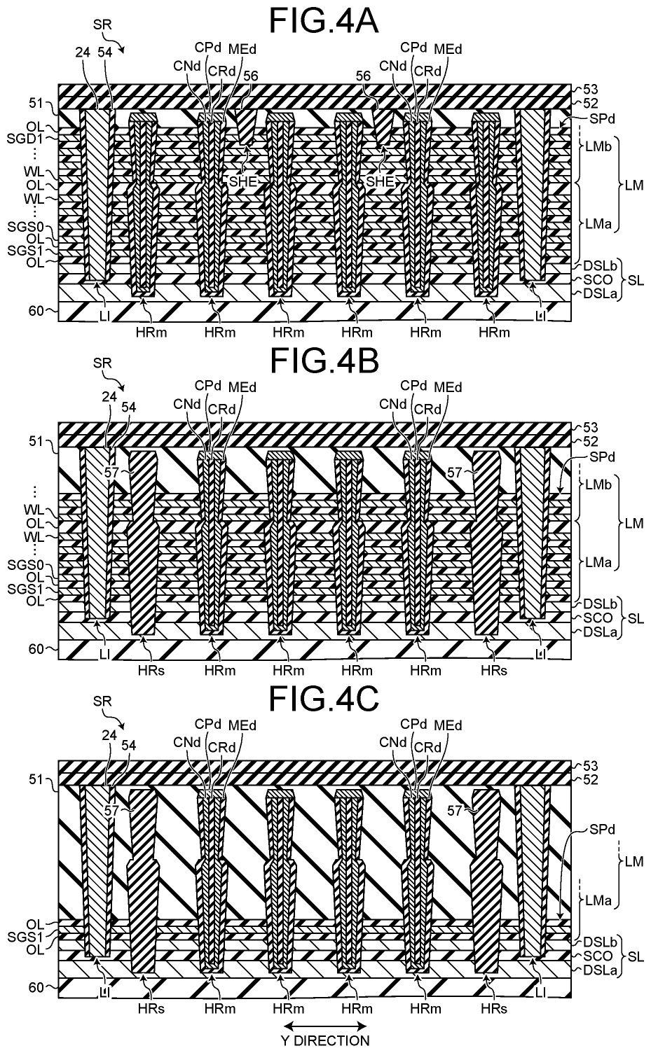

FIGS. 4A to 4C are cross-sectional views of a portion of the step region SR in which the plurality of contacts CC is not arranged, FIG. 4A illustrates a cross section of a portion in which the selection gate line SGD is made stepped, FIG. 4B illustrates a cross section of a portion in which arbitrary word line WL is made stepped, and FIG. 4C illustrates a cross section of a portion in which the selection gate line SGS is made stepped. In FIGS. 4A to 4C, the structure existing below the insulating layer 60 and the structure existing above the insulating layer 53 are omitted.

In addition, in this specification, a direction in which a terrace surface of the word line WL in each step in the step region SR is oriented is defined as an up direction in the semiconductor memory device 1.

As illustrated in FIG. 2A, the source line SL has a multilayer structure in which, for example, a lower source line DSLa, an intermediate source line BSL, and an upper source line DSLb are stacked in this order on the insulating layer 60. Note that the intermediate source line BSL is arranged in a lower portion of the memory region MR of the stacked body LM.

The lower source line DSLa, the intermediate source line BSL, and the upper source line DSLb are, for example, polysilicon layers, or the like. Among these, at least the intermediate source line BSL may be a conductive polysilicon layer or the like in which impurities are dispersed.

In addition, the source line SL is connected to the peripheral circuit CBA via the electrode film EL by a penetration contact (not illustrated) extending from the electrode film EL to the peripheral circuit CBA in the above-described insulating layer 50 on the outside of the stacked body LM.

The stacked body LM is arranged above the source line SL. The stacked body LM includes stacked bodies LMa and LMb in which the plurality of word lines WL and a plurality of insulating layers OL are alternately stacked one by one.

The stacked body LMa is arranged above the source line SL. In a lower layer of the lowermost word line WL in the stacked body LMa, a plurality of selection gate lines SGS0 and SGS1 is arranged in this order from the upper layer side of the stacked body LMa via the insulating layers OL. The stacked body LMb is arranged on the stacked body LMa. In an upper layer of the uppermost word line WL in the stacked body LMb, a plurality of selection gate lines SGD0 and SGD1 is arranged in this order from the upper layer side of the stacked body LMb via the insulating layers OL.

Note that the number of these word lines WL and the selection gate lines SGD and SGS to be stacked in the stacked body LM are arbitrary. The word lines WL and the selection gate lines SGD and SGS are, for example, tungsten layers, molybdenum layers, or the like. The insulating layers OL are, for example, silicon oxide layers or the like.

The top surface of the stacked body LM is covered with an insulating layer 52. The insulating layer 52 is covered with the insulating layer 53. The insulating layers 52 and 53 constitute a part of the insulating layer 50 in FIG. 1A together with an insulating layer 51 to be described later.

As described above, the stacked body LM is divided in the Y direction by the plurality of plate-like contacts LI. That is, the plate-like contacts LI are arranged in the Y direction one another, and extend in the stacking direction of the stacked body LM and the direction along the X direction respectively.

In this manner, the plate-like contacts LI continuously extend in the stacked body LM from one end in the X direction of the stacked body LM toward another end. Further, the plate-like contacts LI penetrate through the stacked body LM and the upper source line DSLb, and reach the intermediate source line BSL in the memory region MR.

Further, the plate-like contact LI has a tapered shape in which a width in the Y direction becomes smaller from an upper end toward a lower end, for example. Alternatively, the plate-like contact LI has a bowing shape in which a width in the Y direction becomes the largest at a predetermined position between the upper end and the lower end, for example.

The plate-like contacts LI each includes an insulating layer 54 and a conductive layer 24. The insulating layer 54 is, for example, a silicon oxide layer or the like. The conductive layer 24 is, for example, a tungsten layer, a conductive polysilicon layer, or the like.

The insulating layer 54 covers side walls of the plate-like contacts LI that face each other in the Y direction. The conductive layer 24 is filled inside the insulating layer 54, and electrically connected to the source line SL including the intermediate source line BSL. Note that, in place of the plate-like contacts LI, by a plate-like member, into which an insulating layer is filled, penetrating through the stacked body LM and extending in the direction along the X direction, the stacked body LM may be divided in the Y direction.

Further, the plurality of separating layers SHE penetrating through the upper layer portion of the stacked body LMb and extending in the direction along the X direction is arranged between the plate-like contacts LI neighboring in the Y direction. These separating layers SHE is an insulating layer 56 such as a silicon oxide layer that penetrates through the selection gate lines SGD0 and SGD1, and reaches the insulating layer OL provided immediately below the selection gate lines SGD1.

In other words, by these separating layers SHE penetrating through the upper layer portion of the stacked body LMb, extending in the X direction in the memory region MR and a part of the step regions SR between the plate-like contacts LI, the upper layer portion of the stacked body LMb is segmented into the above-described selection gate lines SGD0 and SGD1.

In the memory region MR, the plurality of pillars PL penetrating through the stacked body LM, the upper source line DSLb, and the intermediate source line BSL, and reaching the lower source line DSLa is arranged in a dispersed manner.

The plurality of pillars PL has a staggered arrangement, for example, when viewed in the stacking direction of the stacked body LM. Each of the pillars PL has a shape such as a circle, an ellipse, or an oval shape, for example, as a cross-sectional shape in a direction along a layer direction of the stacked body LM, that is to say, a direction along an XY plane.

Further, the pillars PL each have a tapered shape with a diameter and a cross-sectional area becoming smaller from the upper layer side toward the lower layer side, in a portion penetrating through the stacked body LMa, and in a portion penetrating through the stacked body LMb. Alternatively, the pillars PL each have a bowing shape with a diameter and a cross-sectional area becoming the largest at a predetermined position between the upper layer side and the lower layer side, for example, in the portion penetrating through the stacked body LMa, and in the portion penetrating through the stacked body LMb.

The plurality of pillars PL each include a memory layer ME extending in the stacked body LM in the stacking direction, a channel layer CN penetrating through the inside of the stacked body LM and connecting with the intermediate source line BSL, a cap layer CP covering the top surface of the channel layer CN, and a core layer CR serving as a core material of the pillars PL.

As illustrated in FIGS. 2B and 2C, the memory layer ME has a multilayer structure in which a block insulating layer BK, a charge accumulation layer CT, and a tunnel insulating layer TN are stacked in this order from the outer peripheral side of the pillar PL. More specifically, the memory layer ME is arranged on the side surface of the pillar PL except a depth position of the intermediate source line BSL. Further, the memory layer ME is arranged also on the bottom surface of the pillar PL reaching the depth of the lower source line DSLa.

The channel layer CN penetrates through the stacked body LM, the upper source line DSLb, and the intermediate source line BSL, and reaches the depth of the lower source line DSLa on the inside of the memory layer ME. More specifically, the channel layer CN is arranged on the side surface and the bottom surface of the pillar PL via the memory layer ME. Note that a part of the channel layer CN has contact with the intermediate source line BSL on the side surface, and the channel layer CN is thereby electrically connected to the source line SL including the intermediate source line BSL. The core layer CR is filled on the further inside of the channel layer CN.

Further, the plurality of pillars PL each include the cap layer CP at the upper end. The cap layer CP is arranged at the upper end of the pillar PL in such a manner as to cover at least the upper end of the channel layer CN, and connected with the channel layer CN. Further, the cap layer CP is connected with a bit-line BL arranged in the insulating layer 53, via a plug CH arranged in the insulating layer 52. The bit-line BL extends above the stacked body LM in a direction along the Y direction, in such a manner as to intersect with a drawing direction of the word line WL.

In addition, in FIG. 2A, the plug CH is connected only to the three pillars PL respectively penetrating through the selection gate lines SGD separated into three, and electrically connected to the bit-line BL illustrated in FIG. 2A, among the six pillars PL. The other pillars PL are connected via the plug CH not illustrated in FIG. 2A, to another bit-lines BL extending in a direction along the Y direction, concurrently with the bit-line BL illustrated in FIG. 2A, at a position different from the cross section illustrated in FIG. 2A.

The block insulating layer BK, the tunnel insulating layer TN, and the core layer CR of the memory layer ME are, for example, silicon oxide layers or the like. The charge accumulation layer CT of the memory layer ME is a silicon nitride layer or the like, for example. The channel layer CN and the cap layer CP are semiconductor layers such as polysilicon layers or amorphous silicon layers, for example.

As illustrated in FIG. 2C, with the above-described configuration, a memory cell MC is formed at a portion of the side surface of the pillar PL that faces each word line WL. By a predetermined voltage being applied from the word line WL, data writing and readout are performed into and from the memory cell MC.

Further, as illustrated in FIG. 2B, a selection gate STD is formed at a portion of the side surface of the pillar PL that faces the selection gate lines SGD0 and SGD1 in a further upper layer of the word line WL. Further, a selection gate STS is formed at a portion of the side surface of the pillar PL that faces the selection gate lines SGS0 and SGS1 in a further lower layer of the word line WL.

By predetermined voltages being applied from the selection gate lines SGD and SGS, the selection gates STD and STS are turned on or off, and the memory cells MC of the pillars PL to which the selection gates STD and STS belong can be brought into a selected state or an unselected state.

As illustrated in FIGS. 3A to 4C, the step region SR includes step portions SP and SPd in which the plurality of word lines WL and the selection gate lines SGD and SGS are processed in a step-like shape.

The step portion SP illustrated in FIGS. 3A to 3C is a portion in which the contact CC is arranged, and is a portion having a drawing function of the word line WL and the like, in the step region SR divided in the plurality of block regions BLK. The step portion SPd illustrated in FIGS. 4A to 4C is a portion in which the contact CC is not arranged, is a portion not having a drawing function of the word line WL and the like, and is a dummy configuration, in the step region SR divided in the plurality of block regions BLK.

That is, when viewed on one side in the X direction of the stacked body LM, the step portion SP and the step portion SPd are alternately arranged every two block regions BLK arranged in the Y direction.

These step portions SP and SPd are covered with the insulating layer 51. The insulating layer 51 reaches the height position of the uppermost layer of the stacked body LM, for example, and the insulating layers 52 and 53 cover also the top surface of the insulating layer 51. As described above, the insulating layer 51 also constitutes a part of the insulating layer 50 in FIG. 1A.

Further, in the step region SR, the source line SL includes an intermediate insulating layer SCO interposed between the upper source line DSLb and the lower source line DSLa, in place of the intermediate source line BSL. The intermediate insulating layer SCO is, for example, a silicon oxide layer or the like.

Thus, in the step region SR, the plate-like contacts LI penetrate through the insulating layer 51, the stacked body LM, and the upper source line DSLb, and reach the intermediate insulating layer SCO.

Further, in the step region SR, a plurality of columnar portions HRm and HRs is arranged over the entire region, and the plurality of contacts CC is partially arranged. As described later, these columnar portions HRm and HRs have a function of, when forming the stacked body LM from a stacked body in which sacrificial layers and insulating layers are stacked, supporting these components, and do not contribute to the function of the semiconductor memory device 1.

As illustrated in FIGS. 3A to 3C, each of the contacts CC penetrates through the insulating layer 51, and is connected to the word line WL or the selection gate line SGD or SGS existing immediately below the insulating layer OL that forms each step of the step portion SP.

Each of the contact CC has a tapered shape with a diameter and a cross-sectional area becoming smaller from the upper end toward the lower end, for example. Alternatively, the contact CC has a bowing shape in which a diameter and a cross-sectional area become the largest at a predetermined position between the upper end and the lower end, for example.

Further, the contact CC includes an insulating layer 55 covering the outer periphery of the contact CC, and a conductive layer 25 such as a tungsten layer or a copper layer that is filled into the insulating layer 55. The conductive layer 25 is connected with an upper layer wire MX arranged in the insulating layer 53, via a plug VO arranged in the insulating layer 52. The upper layer wire MX is electrically connected to the above-described peripheral circuit CBA (refer to FIG. 1A).

With such a configuration, each layer of the word lines WL and the selection gate lines SGD and SGS above or below the word line WL can be electrically drawn from one end side or another end side in the X direction of the stacked body LM. That is, with the above-described configuration, by applying a predetermined voltage from the peripheral circuit CBA to the memory cell MC via the upper layer wire MX, the contact CC, the word line WL, and the like, the memory cell MC can be operated as a storage element.

FIG. 3A illustrates the step portion SP in a portion in which the selection gate lines SGD and the insulating layers OL are processed in a step-like shape for one pair. In the step portion SP illustrated in FIG. 3A, besides the contact CC connected to the selection gate lines SGD 1, the plurality of columnar portions HRm penetrating through the insulating layer 51, the stacked bodies LMb and LMa, the upper source line DSLb, and the intermediate insulating layer SCO, and reaching the lower source line DSLa is arranged in a dispersed manner.

In a portion in which the selection gate line SGD is processed in a step-like shape, the plurality of contacts CC connected to the respective sections of the selection gate line SGD separated by the separating layer SHE is arranged for one selection gate line SGD.

While avoiding interference with the plate-like contact LI and the contact CC, the plurality of columnar portions HRm has, for example, grid-like or staggered arrangement when viewed from the stacking direction of the stacked body LM. Each of the columnar portion HRm has a shape such as a circle, an ellipse, or an oval shape, for example, as a cross-sectional shape in the direction along the XY plane.

Further, the columnar portions HRm each have a tapered shape with a diameter and a cross-sectional area becoming smaller from the upper layer side toward the lower layer side, in a portion penetrating through the stacked body LMa, and in a portion penetrating through the stacked body LMb. Alternatively, the columnar portions HRm each have a bowing shape with a diameter and a cross-sectional area becoming the largest at a predetermined position between the upper layer side and the lower layer side, for example, in the portion penetrating through the stacked body LMa, and in the portion penetrating through the stacked body LMb.

Each of the plurality of columnar portions HRm has the same layer structure as the above-described pillars PL. However, the plurality of columnar portions HRm is in a floating state as a whole, and as described above, does not have an electrical function in the semiconductor memory device 1.

Further, by the columnar portion HRm being arranged while avoiding interference with the plate-like contact LI and the contact CC as described above, the influence exerted by the columnar portion HRm having a similar layer structure to that of the pillars PL is suppressed.

As the same layer structure as that of the pillars PL, the columnar portion HRm includes dummy layers MEd, CNd, and CRd extending in the stacked body LM in the stacking direction.

As illustrated in FIG. 2D, the dummy layer MEd has a multilayer structure in which dummy layers BKd, CTd, and TNd are stacked in this order from the outer periphery side of the columnar portion HRm. That is to say, the dummy layer MEd corresponds to the memory layer ME of the above-described pillar PL. Further, the dummy layers BKd, CTd, and TNd included in the dummy layer MEd respectively correspond to the block insulating layer BK, the charge accumulation layer CT, and the tunnel insulating layer TN of the pillar PL.

Note that the dummy layer MEd is continuously arranged on the side surface of the columnar portion HRm from the upper source line DSLb to the lower source line DSLa. The dummy layer MEd is arranged also at the lower end of the columnar portion HRm.

The dummy layer CNd penetrates through the stacked body LM, the upper source line DSLb, and the intermediate insulating layer SCO, and reaches the depth of the lower source line DSLa on the inside of the dummy layer MEd. The dummy layer CNd correspond to the channel layer CN of the above-described pillar PL.

Note that the dummy layer MEd is arranged on the side surface of the dummy layer CNd from the upper source line DSLb to the lower source line DSLa, and furthermore, the intermediate insulating layer SCO is arranged between the upper source line DSLb and the lower source line DSLa. Thus, the dummy layer CNd does not have electric conduction with the source line SL. The dummy layer CRd is filled into the further inside of the dummy layer CNd. The dummy layer CRd correspond to the core layer CR of the above-described pillar PL.

Further, each of the plurality of columnar portions HRm includes a dummy layer CPd at the upper end. The dummy layer CPd is arranged at the upper end of the columnar portion HRm in such a manner as to cover at least the upper end of the dummy layer CNd, and connected with the dummy layer CNd. The dummy layer CPd correspond to the cap layer CP of the above-described pillar PL. Note that the above-described plug CH, the bit-line BL, and the like are not connected to the dummy layer CPd. The dummy layer CPd itself needs not be included in the columnar portion HRm.

The layers included in the columnar portion HRm contain materials of the same types as corresponding layers of the pillars PL. That is to say, the dummy layers BKd and TNd, and the dummy layer CRd of the dummy layer MEd are, for example, silicon oxide layers or the like. The dummy layer CTd is, for example, a silicon nitride layer or the like. The dummy layers CNd and CPd are semiconductor layers such as polysilicon layers or amorphous silicon layers, for example. Here, the semiconductor material included in the dummy layer CNd and the like has higher Young's modulus than those of materials included in the other dummy layers MEd and CRd, for example, and has a property of being strong and less deformable.

FIG. 3B illustrates the step portion SP in a portion in which the word lines WL and the insulating layers OL are processed in a step-like shape for one pair. In the step portion SP illustrated in FIG. 3B, besides the contact CC connected to the word line WL serving as a terrace portion, the columnar portions HRm and HRs penetrating through the insulating layer 51, the stacked bodies LMb and LMa, the upper source line DSLb, and the intermediate insulating layer SCO, and reaching the lower source line DSLa are arranged.

The columnar portion HRs is arranged in the vicinity of the contact CC. Further, the columnar portions HRs are arranged adjacently at the Y direction both sides of the plate-like contact LI. Each of the columnar portion HRs has a shape such as a circle, an ellipse, or an oval shape, for example, as a cross-sectional shape in the direction along the XY plane.

Further, the columnar portions HRs each have a tapered shape with a diameter and a cross-sectional area becoming smaller from the upper layer side toward the lower layer side, in a portion penetrating through the stacked body LMa, and in a portion penetrating through the stacked body LMb. Alternatively, the columnar portions HRs each have a bowing shape with a diameter and a cross-sectional area becoming the largest at a predetermined position between the upper layer side and the lower layer side, for example, in the portion penetrating through the stacked body LMa, and in the portion penetrating through the stacked body LMb.

The columnar portion HRs is a single body of an insulating layer 57 entirely made of a silicon oxide layer or the like. That is to say, the columnar portion HRs is formed of the insulating layer 57 made of a substantially single material. Here, being made of a substantially single material can include a case where an element ratio of structural components of these columnar portions HRs varies within one columnar portion HRs or among a plurality of columnar portions HRs, and a case where the type and an amount of contained impurity varies, and further permits voids to be included in the columnar portion HRs of a single material.

Because the columnar portion HRs is a single body of the insulating layer 57 in this manner, the columnar portion HRs dose not exert electric influence on other components, and is permitted to interfere with the neighboring plate-like contacts LI and the contact CC.

In the step portion SP on the lower layer side in which the plurality of word lines WL and the like are processed in a step-like shape, the plurality of columnar portions HRm are arranged in a dispersed manner over the entire step portion SP excluding the vicinity of the contact CC and positions neighboring the plate-like contact LI. On the lower layer side of the step portion SP, the columnar portion HRs is arranged in the vicinity of the contact CC and at a position neighboring the plate-like contact LI, in place of the columnar portion HRm for the following reason.

In the plate-like contact LI, a region arranged in the insulating layer 51 tends to have a larger degree of a tapered shape or a bowing shape than that of a region arranged in the stacked body LM. That is to say, in a case where the plate-like contact LI has a tapered shape, in the insulating layer 51, a difference between a width at the upper end and a width at the lower end of the plate-like contact LI is likely to become larger. In a case where the plate-like contact LI has a bowing shape, in the insulating layer 51, a difference between the greatest width of the plate-like contact LI and widths at the upper and lower ends of the plate-like contact LI is likely to become larger.

Further, as a distance by which the plate-like contact LI extends in the insulating layer 51 in the stacking direction of the stacked body LM becomes longer, the degree of the tapered shape or the bowing shape is likely to become further larger. That is to say, in the step region SR, rather than a region in which each layer on the upper layer side of the stacked body LM is processed in a step-like shape, in a region in which each layer on the lower layer side of the stacked body LM is processed in a step-like shape, the tapered shape or the bowing shape of the plate-like contact LI is likely to become prominent.

The above-described point is similarly to applied to the contact CC. Rather than the contact CC connected to a layer on the upper layer side of the stacked body LM, the contact CC connected to a layer on the lower layer side of the stacked body LM has a longer distance by which the contact CC extends in the insulating layer 51 in the stacking direction of the stacked body LM. That is to say, the tapered shape or the bowing shape of the contact CC connected to the layer on the lower layer side of the stacked body LM is likely to become prominent.

Accordingly, on the lower layer side of the step portion SP on which the greatest diameter of the contact CC and the greatest width of the plate-like contact LI tend to increase, and contact risk also increases, the columnar portions HRs are arranged in place of the columnar portion HRm in the vicinity of the contact CC and at the position neighboring the plate-like contact LI. With this configuration, it is possible to densely arrange the columnar portions HRs while permitting contact with the contact CC or the plate-like contact LI to some extent.

FIG. 3C illustrates the step portion SP in a portion in which the selection gate lines SGS and the insulating layers OL are processed in a step-like shape for one pair. Also in a portion in which the selection gate line SGS is processed in a step-like shape, the step portion SP has a configuration similar to the above-described configuration in FIG. 3B. That is, in the step portion SP illustrated in FIG. 3C, besides the contact CC connected to the selection gate line SGS 1, the columnar portions HRs are arranged in the vicinity of the contact CC and at the position neighboring the plate-like contact LI, and the columnar portion HRm arranged separately from the contact CC or the plate-like contact LI are arranged.

As illustrated in FIGS. 4A to 4C, the components of the step portion SPd also have a configuration substantially similar to that of the above-described step portion SP illustrated in FIGS. 3A to 3C, except that the plurality of contacts CC is not arranged.

FIG. 4A illustrates the step portion SPd in a portion in which the selection gate lines SGD and the insulating layers OL are processed in a step-like shape for one pair. In a portion in which the selection gate line SGD is processed in a step-like shape, similarly to FIG. 3A described above, in the step portion SPd, the plurality of columnar portions HRm is arranged in a dispersed manner over the entire step portion SPd.

FIG. 4B illustrates the step portion SPd in a portion in which the word lines WL and the insulating layers OL are processed in a step-like shape for one pair. FIG. 4C illustrates the step portion SPd in a portion in which the selection gate lines SGS and the insulating layers OL are processed in a step-like shape for one pair.

In a portion in which the word line WL is processed in a step-like shape, and in a portion in which the selection gate line SGS is processed in a step-like shape, in the step portion SPd, similarly to FIGS. 3B and 3C described above, a plurality of columnar portions HRs is arranged adjacently to the plate-like contact LI in the Y direction.

On the other hand, because the contact CC is not arranged in the step portion SPd, the plurality of columnar portions HRm is arranged in a dispersed manner over the entire step portion SPd excluding the position neighboring the plate-like contact LI.

In addition, at the same height position of the stacked body LM, cross-sectional areas of the columnar portions HRm and HRs in the direction along the XY plane are larger than a cross-sectional area of the pillar PL, for example, in the direction along the XY plane. Further, a pitch between the plurality of columnar portions HRm and a pitch between the plurality of columnar portions HRs are larger than a pitch between the plurality of pillars PL, for example, and arrangement densities of the columnar portions HRm and HRs per unit area of the word line WL in the stacked body LM are lower than the arrangement density of the pillars PL per unit area of the word line WL.

In this manner, for example, by making a cross-sectional area of the pillars PL smaller as compared with those of the columnar portions HRm and HRs, and employing a narrow pitch, it is possible to form a larger number of the memory cells MC at high density within the stacked body LM having a predetermined size, and increase the storage capacity of the semiconductor memory device 1. On the other hand, because the columnar portions HRm and HRs are mainly used to support the stacked body LM, by avoiding a precise configuration with a small cross-sectional area and a narrow pitch like the pillars PL, for example, it is possible to down-grade the process control method.

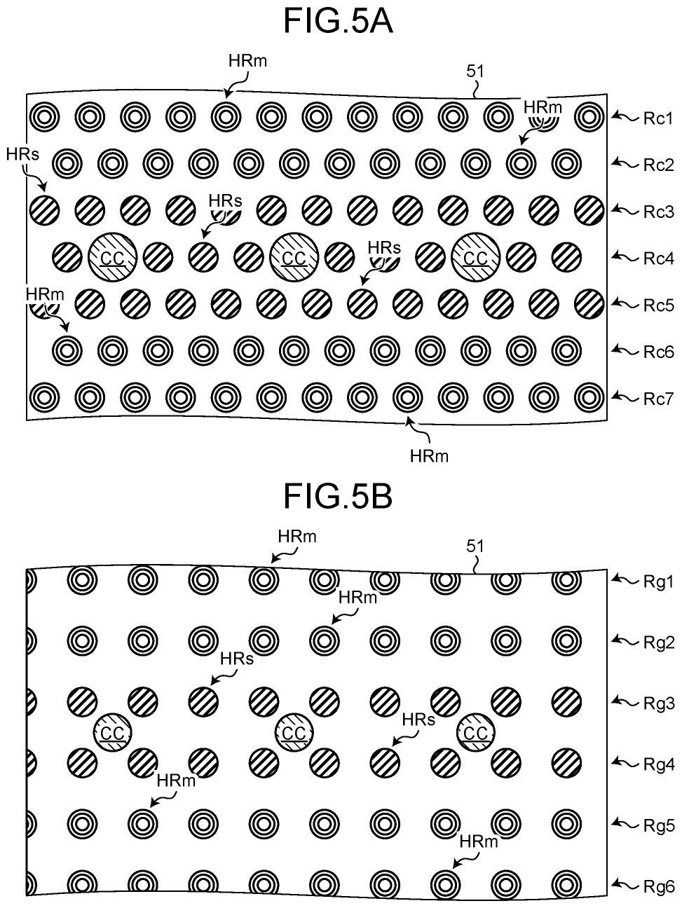

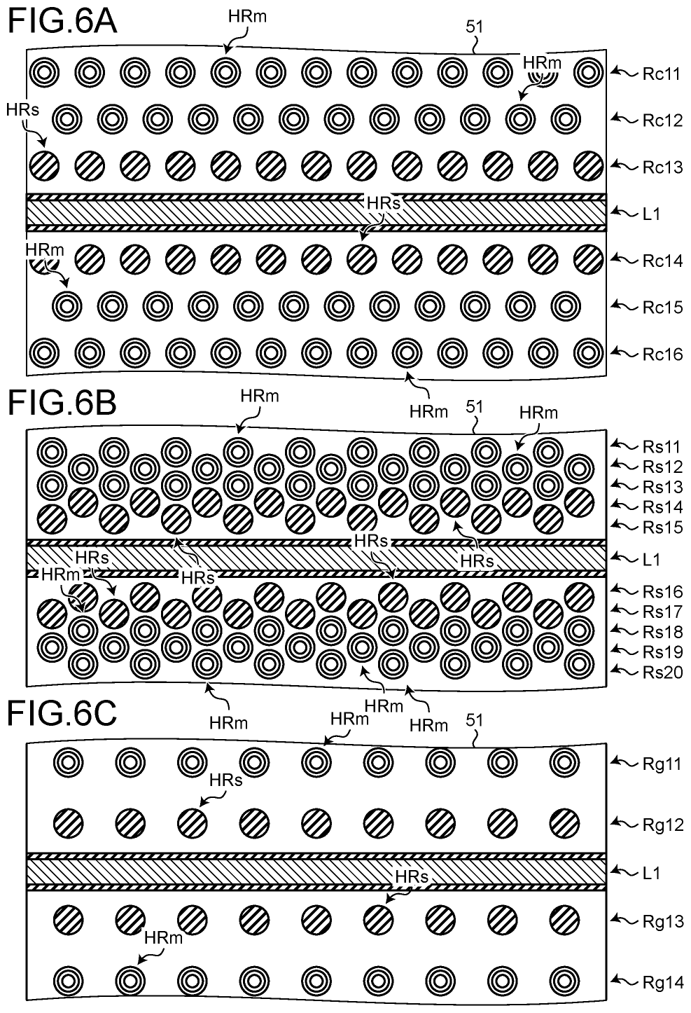

Next, an arrangement example of the columnar portions HRm and HRs will be described in detail with reference to FIGS. 5A to 6C. FIGS. 5A to 6C are XY cross-sectional views at an arbitrary height position in the insulating layer 51 covering a step portion SP that illustrate an arrangement example of the columnar portions HRm and HRs according to the first embodiment.

FIGS. 5A and 5B illustrate several arrangement examples of the columnar portions HRm and HRs in the vicinity of the contacts CC connected to the several word lines WL. As described above, the columnar portions HRm and HRs are arranged in a staggered or grid manner, for example. FIG. 5A illustrates an example of the columnar portions HRm and HRs having staggered arrangement, and FIG. 5B illustrates an example of the columnar portions HRm and HRs having grid-like arrangement.

As illustrated in FIGS. 5A and 5B, in accordance with the terrace portions of the word lines WL in the upper and lower layers being arranged adjacently in the X direction, the plurality of contacts CC is arranged on at least one line in the direction along the X direction, for example.

In such a configuration, when the arrangement of the columnar portions HRm and HRs is determined, for example, for each of a plurality of arrays extending in the direction along the X direction, either of the columnar portions HRm and HRs to be arranged is selected. In this case, among the plurality of arrays of the columnar portions HRm and HRs, on an array including a point proximal to the contact CC, the columnar portion HRs permitted to interfere with the contact CC to some extent is arranged. Further, the columnar portions HRm assumed to avoid interference with the contacts CC are arranged on the other arrays.

In the example illustrated in FIG. 5A, around each of the contacts CC, six columnar portions HRs are arranged in such a manner as to surround the contact CC. That is to say, arrangement points of one pair of columnar portions HRs sandwiching the contact CC from the X direction both sides, and two pairs of columnar portions HRs sandwiching the contact CC from the Y direction both sides are proximal to the contact CC, and are point with high contact risks with the contacts CC.

When this is viewed for each of a plurality of arrays Rc1 to Rc7 of the columnar portions HRm and HRs extending in the direction along the X direction, the above-described six columnar portions HRs proximal to the contacts CC are included in any of the arrays Rc3 to Rc5.

Among the arrays Rc3 to Rc5, the array Rc4 entirely overlaps the array positions of the contacts CC in the X direction. Thus, the array Rc4 includes points on both sides in the X direction of the contact CC that have high contact risk with the contacts CC.

In a case where an array includes a point proximal to the contact CC, such as entirely overlapping the array positions of the contacts CC in the X direction like this array Rc4, for example, the columnar portions HRs are arranged on the array.

Further, among the arrays Rc3 to Rc5, the arrays Rc3 and Rc5 arranged apart from the contacts CC in the Y direction neighbor the array positions of the contacts CC in the Y direction. Thus, the arrays Rc3 and Rc5 neighboring the array positions of the contacts CC in the Y direction include points on both sides in the Y direction of the contact CC that have high contact risk with the contacts CC.

Here, an array neighboring the array positions of the contacts CC in the Y direction is an array arranged without another array being interposed between the array itself and the array of the contacts CC in the Y direction. That is, other arrays of the columnar portions HRm and HRs are not interposed between the arrays Rc3 and Rc5 and the array of the contact CC.

In a case where an array includes a point proximal to the contact CC, such as neighboring the array positions of the contacts CC in the Y direction like these arrays Rc3 and Rc5, for example, the columnar portions HRs are arranged on the array.

In the example illustrated in FIG. 5B, around each of the contacts CC, four columnar portions HRs are arranged in such a manner as to surround the contact CC. That is to say, arrangement points of two pairs of columnar portions HRs sandwiching the contact CC from the X direction both sides are proximal to the contact CC, and are point with high contact risks with the contacts CC.

When this is viewed for each of a plurality of arrays Rg1 to Rg6 of the columnar portions HRm and HRs extending in the direction along the X direction, the above-described four columnar portions HRs proximal to the contacts CC are included in either of the arrays Rg3 and Rg4. The arrays Rg3 and Rg4 partially overlap the array positions of the contacts CC in the X direction.

That is to say, the end on the contact CC side in the Y direction of the columnar portion HRs belonging to the array Rg3 is positioned closer to the center in the Y direction of the contact CC than the end on the array Rg3 side in the Y direction of the contact CC. Similarly, the end on the contact CC side in the Y direction of the columnar portion HRs belonging to the array Rg4 is positioned closer to the center in the Y direction of the contact CC than the end on the array Rg4 side in the Y direction of the contact CC.

In this case, the arrays Rg3 and Rg4 both include points on both sides in the X direction of the contact CC that have high contact risk with the contacts CC.

In a case where an array includes a point proximal to the contact CC, such as partially overlapping the array positions of the contacts CC in the X direction like these arrays Rg3 and Rg4, for example, the columnar portions HRs are arranged on the array. Accordingly, the columnar portions HRs are arranged on the arrays Rg3 and Rg4.

As described above, among the plurality of arrays of the columnar portions HRm and HRs, an array overlapping the array positions of the contacts CC at least partially in the X direction and an array neighboring the array positions of the contacts CC in the Y direction, include points proximal to the contacts CC. Thus, the columnar portions HRs are accordingly arranged on these arrays.

In contrast to this, the columnar portion HRm is arranged on an array away in the Y direction from the array positions of the contacts CC. That is, the columnar portions HRm are arranged on an array not including a portion overlapping the array positions of the contacts CC in the X direction, and on an array not neighboring the array positions of the contacts CC in the Y direction. This is because such an array does not include a point proximal to the contact CC.

As illustrated in FIG. 5A, among the plurality of arrays Rc1 to Rc7 of the columnar portions HRm and HRs, the arrays Rc2 and Rc6 do not include a portion overlapping the array positions of the contacts CC in the X direction. Further, the arrays Rc3 and Rc5 are respectively interposed between the arrays Rc2 and Rc6 and the array of the contacts CC, and the arrays Rc2 and Rc6 do not neighbor the array of the contacts CC in the Y direction. Accordingly, the columnar portions HRm are arranged on both of the arrays Rc2 and Rc6.

Further, as a matter of course, as for the arrays Rc1 and Rc7 further away from the contacts CC than the arrays Rc2 and Rc6, the arrangement with respect to the contact CC falls outside the above-described definition. Accordingly, the columnar portions HRm are arranged also on these arrays Rc1 and Rc7.

As illustrated in FIG. 5B, among the plurality of arrays Rg1 to Rg6 of the columnar portions HRm and HRs, the arrays Rg2 and Rg5 do not include a portion overlapping the array positions of the contacts CC in the X direction. Further, the arrays Rg3 and Rg4 are respectively interposed between the arrays Rg2 and Rg5 and the array of the contacts CC, and the arrays Rg2 and Rg5 do not neighbor the array of the contacts CC in the Y direction. Accordingly, the columnar portions HRm are arranged on both of the arrays Rg2 and Rg5.

Further, as a matter of course, as for the arrays Rg1 and Rg6 further away from the contacts CC than the arrays Rg2 and Rg5, the arrangement with respect to the contact CC falls outside the above-described definition. Accordingly, the columnar portions HRm are arranged also on these arrays Rg1 and Rg6.

As described above, for example, instead of arranging the columnar portions HRs only at very limited points around the contacts CC, by arranging either of the columnar portions HRs and HRm for each of the arrays of the columnar portions HRs and HRm arranged on a plurality of arrays, the configuration of the step portion SP around the contacts CC becomes simple.

FIGS. 6A to 6C illustrate several arrangement examples of the columnar portions HRm and HRs in the vicinity of the plate-like contact LI. FIG. 6A illustrates an example of the columnar portions HRm and HRs having staggered arrangement, FIG. 6B illustrates another example of the columnar portions HRm and HRs having staggered arrangement, and FIG. 6C illustrates an example of the columnar portions HRm and HRs having grid-like arrangement.

In the vicinity of the plate-like contact LI, when the arrangement of the columnar portions HRm and HRs is determined, for example, for each of a plurality of arrays extending in the direction along the X direction, it is considered whether a corresponding array is proximal to the plate-like contact LI. On an array neighboring the plate-like contact LI in the Y direction, the columnar portion HRs is arranged as an array proximal to the plate-like contact LI.

As illustrated in FIG. 6A, among a plurality of arrays Rc11 to Rc16 of the columnar portions HRm and HRs that extends in the direction along the X direction, other arrays of the columnar portions HRm and HRs are not interposed between the arrays Rc13 and Rc14 arranged apart from the plate-like contact LI in the Y direction, and the plate-like contact LI. That is to say, the arrays Rc13 and Rc14 neighbor the plate-like contact LI in the Y direction, and the columnar portions HRs are arranged on the arrays Rc13 and Rc14.

In the example illustrated in FIG. 6B, the columnar portions HRm and HRs having staggered arrangement are arranged at higher density. With this configuration, among a plurality of arrays Rs11 to Rs20 of the columnar portions HRm and HRs that extends in the direction along the X direction, mutually neighboring arrays Rs11 and Rs12, arrays Rs12 and Rs13, arrays Rs13 and Rs14, arrays Rs14 and Rs15, arrays Rs16 and Rs17, arrays Rs17 and Rs18, arrays Rs18 and Rs19, and arrays Rs19 and Rs20 partially overlap each other in the X direction.

As illustrated in FIG. 6B, among the plurality of arrays Rs11 to Rs20 of the columnar portions HRm and HRS, the arrays Rs15 and Rs16 are arranged at positions closest to the plate-like contact LI in the Y direction, and other arrays of the columnar portions HRm and HRs are not interposed between these arrays Rs15 and Rs16 and the plate-like contact LI. That is to say, the arrays Rs15 and Rs16 neighbor the plate-like contact LI, and the columnar portions HRs are arranged on the arrays Rs15 and Rs16.

Further, when attention is focused on the arrays Rs14 and Rs17 arranged further apart from the plate-like contact LI in the Y direction than the arrays Rs15 and Rs16, as described above, the arrays Rs14 and Rs15, and the arrays Rs16 and Rs17 overlap each other in the X direction. Thus, it cannot be said that the arrays Rs15 and Rs16 are interposed between the arrays Rs14 and Rs17 and the plate-like contact LI, and the arrays Rs14 and Rs17 are also arrays neighboring the plate-like contact LI, and the columnar portions HRs are arranged also on the arrays Rs14 and Rs17.

In this manner, in a case where the arrangement density of the columnar portions HRm and HRs is high, or the like, assuming that a plurality of arrays on one side in the Y direction of the plate-like contact LI is arrays neighboring the plate-like contact LI, the columnar portions HRs may be arranged on the plurality of arrays.

As illustrated in FIG. 6C, among a plurality of arrays Rg11 to Rg14 of the columnar portions HRm and HRs that extends in the direction along the X direction, other arrays of the columnar portions HRm and HRs are not interposed between the arrays Rg12 and Rg13 and the plate-like contact LI. That is to say, the arrays Rg12 and Rg13 neighbor the plate-like contact LI in the Y direction, and the columnar portions HRs are arranged on the arrays Rg12 and Rg13.

In contrast to this, the columnar portions HRm are arranged on an array that is away in the Y direction also from the plate-like contact LI in addition to the contact CC. That is, the columnar portions HRm are arranged on an array not neighboring the plate-like contact LI in the Y direction.

As described above, the examples illustrated in FIGS. 6A to 6C are applied also to the step portion SPd in which the contact CC is not arranged. That is, also in the step portion SPd, the columnar portions HRs are arranged on one or the plurality of arrays neighboring the plate-like contact LI on one side in the Y direction. Further, in the step portion SPd, the columnar portions HRm are arranged in a dispersed manner on the plurality of arrays excluding a position neighboring the plate-like contact LI in the Y direction.

Note that numbers allocated to the arrays of the arrays Rc1 to Rc7, Rc11 to Rc16, Rs11 to Rs20, Rg1 to Rg6, Rg11 to Rg14, and the like of the columnar portions HRm and HRs illustrated in FIGS. 5A to 6C described above are provided to identify these, and are not intended to indicate the actual numbers of arrays of the columnar portions HRm and HRS.

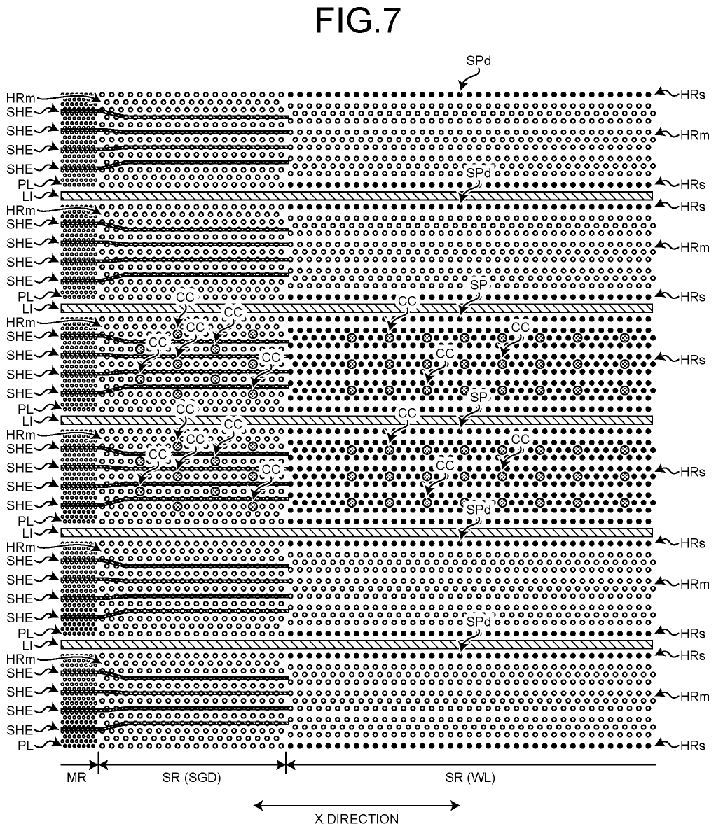

FIG. 7 illustrates an application example in which the columnar portions HRm and HRs are arranged in accordance with the above-described prescription.

FIG. 7 is a schematic diagram illustrating one of application examples in a case where the columnar portions HRm and HRs are arranged on the basis of the prescription in the semiconductor memory device 1 according to the first embodiment. More specifically, FIG. 7 is an XY cross-sectional view at the height position of the selection gate lines SGD, and includes a part of the step region SR on one side of the stacked body LM in the X direction and a part of the memory region MR.

As illustrated in FIG. 7, in the step region SR on one side of the stacked body LM in the X direction, the step portion SP to which the contact CC is connected, and the step portion SPd to which the contact CC is not connected are alternately arranged every two block regions BLK divided by the plate-like contact LI.

In these step portions SP and SPd, a region separated by the separating layer SHE extending from the memory region MR correspond to a portion in which the selection gate lines SGD are processed in a step-like shape. A region extending from the end in the X direction of the separating layer SHE is a portion in which the plurality of word lines WL is processed in a step-like shape.

When attention is focused on the step portion SP in FIG. 7, two contacts CC are arranged for each of sections of the selection gate lines SGD separated by the separating layer SHE. That is to say, in the example in FIG. 7, the stacked body LM includes two layers of the selection gate lines SGD.

Further, in a portion in the step portion SP in which the word line WL is processed in a step-like shape, for each block region BLK divided by the plate-like contact LI, the contacts CC arrayed in the direction along the X direction are arranged on three arrays. This is because, in the example in FIG. 7, the step portion SP is formed in such a manner that, as described above, as getting away from the memory region MR, the word line WL and the selection gate line SGS that form the terrace surface of the step portion SP shift toward the lower layer side, and shift also as getting toward the Y direction.

In this manner, a step structure in which the layer of the word line WL and the like that form the terrace surface changes not only in the X direction but also in the Y direction will also be referred to as a multiple-array step. That is to say, the step structure described above shown in FIG. 7, in which the layer changes in the Y direction in three steps is a three-array step. In the multiple-array step, in at least one direction of the X direction and the Y direction, one step can include the word line WL and the like in a multilayer.

Further, irrespective of whether a step is the multiple-array step, the step portion SP can include a step portion in which each step lowers toward the memory region MR in such a manner that each step faces the lowering step portion as getting away from the memory region MR. While the contact CC is connected as described above to the step portion lowering in a direction of getting away from the memory region MR, the word line WL and the like in the step portion lowering toward the memory region MR are in the floating state, for example, and the contact CC is not connected thereto.

That is, the step portions SP and SPd may be formed by making the layers of the word line WL and the selection gate line SGS forming the terrace surfaces arranged different from each other in the Y direction at the same position in the X direction. As above described, FIG. 7 illustrates an example of a three-array step in which terrace surfaces of three layers consecutive in the stacking direction of the word line WL and the selection gate line SGS are arranged in the Y direction at the same position in the X direction. In the example illustrated in FIG. 7 having such a configuration, to connect to the word line WL and the selection gate line SGS in each layer, three contacts CC are also arranged in the Y direction at the same position in the X direction.

Further, in the example illustrated in FIG. 7, both of a plurality of pillars and a plurality of columnar portions HRm and HRs have staggered arrangement. The number of arrays of the pillars PL arranged in the direction along the X direction, within one block region BLK is 20.

On the other hand, a diameter and a pitch of the columnar portions HRm and HRs are made larger than a diameter and a pitch of the pillars PL. Thus, the columnar portions HRm and HRs arranged within one block region BLK in the direction along the X direction are arranged on 13 arrays in a portion in which the selection gate lines SGD are processed in a step-like shape, and are arranged on 11 arrays in a portion in which the word line WL and the selection gate line SGS are processed in a step-like shape.

In the step portion SP or SPd having such a configuration, in the portion in which the selection gate lines SGD is processed in a step-like shape, the columnar portions HRm are arranged in a dispersed manner on the plurality of arrays over the entire one block region BLK including the vicinity of the contact CC and a position neighboring the plate-like contact LI.

Further, in the portion of the step portion SP in which the word line WL and the selection gate line SGS are processed in a step-like shape, the columnar portions HRs are arranged at a position proximal to the contact CC, or neighboring the plate-like contact LI, and the columnar portions HRs are consequently arranged in a dispersed manner on the plurality of arrays over the entire one block region BLK.

That is, on one array of the contacts CC arranged on three arrays extending in the direction along the X direction, one array entirely overlapping the array positions of the contacts CC in the X direction, and two arrays neighboring the array positions of the contacts CC on the Y direction both sides are arrays including points proximal to the contact CC, and the columnar portions HRs are arranged on these arrays.

In this manner, for one array of the contacts CC, the columnar portions HRs are arranged on three arrays surrounding this one array. In addition to these, the columnar portions HRs are arranged on arrays neighboring the plate-like contacts LI on the Y direction both sides of the block region BLK. Consequently, the columnar portions HRs are arranged over the entire block region BLK.

Further, in the portion of the step portion SPd in which the word line WL and the selection gate line SGS are processed in a step-like shape, the columnar portions HRs are arranged on one array neighboring the plate-like contacts LI on the Y direction both sides of the block region BLK. Further, the columnar portions HRm are arranged on nine arrays on the inside of these arrays.

### (Manufacturing Method of Semiconductor Memory Device)

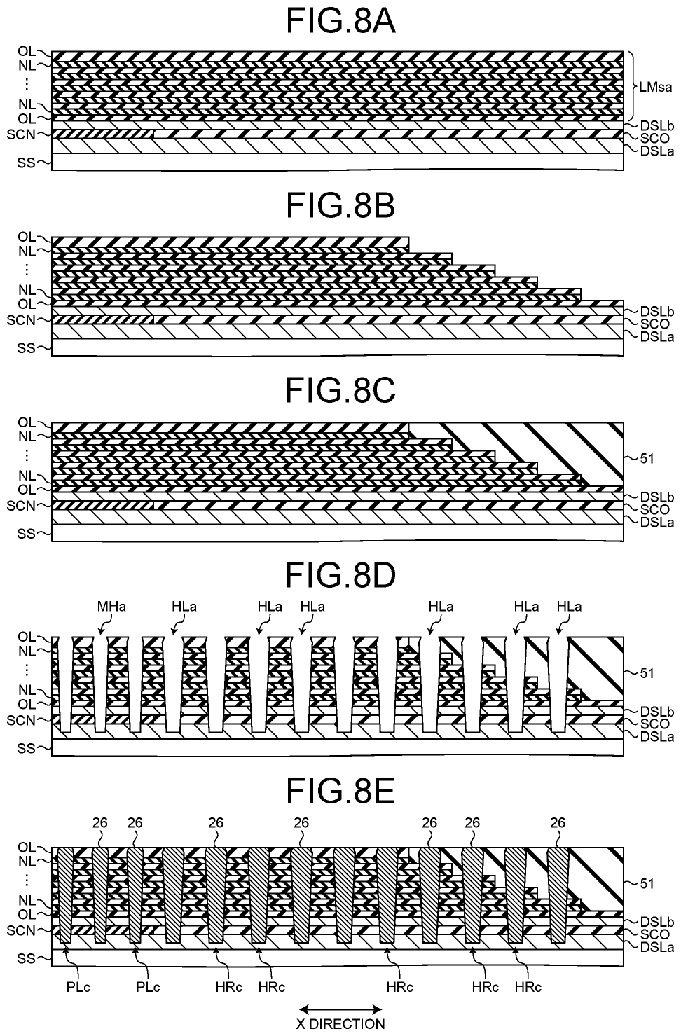

Next, a manufacturing method of the semiconductor memory device 1 of the first embodiment will be described with reference to FIGS. 8A to 20C. FIGS. 8A to 20C are diagrams sequentially exemplifying a part of procedures of a manufacturing method of the semiconductor memory device 1 according to the first embodiment.

First of all, FIGS. 8A to 8E illustrate a procedure of forming a stacked body LMsa being a lower layer portion of the stacked body LM before the word line WL is formed, and forming various components on the stacked body LMsa.

FIGS. 8A to 8E are cross-sectional views along the X direction that illustrate regions latterly becoming the memory region MR and the step region SR.

As illustrated in FIG. 8A, the lower source line DSLa, an intermediate sacrificial layer SCN or the intermediate insulating layer SCO, and the upper source line DSLb are formed in this order on a support substrate SS.

As the support substrate SS, a semiconductor substrate such as a silicon substrate, an insulating substrate such as a ceramic substrate, a conductive substrate, or the like can be used. On the top surface side of the support substrate SS, the above-described insulating layer 60 (refer to FIG. 2A and the like) may be formed.

The intermediate sacrificial layer SCN is formed in a region on the support substrate SS that latterly becomes the memory region MR, and the intermediate insulating layer SCO is formed in a region on the support substrate SS that latterly becomes the step region SR. The intermediate sacrificial layer SCN is, for example, a silicon nitride layer or the like, and is a layer that is latterly replaced with a polysilicon layer or the like to become the intermediate source line BSL. The intermediate insulating layer SCO is, for example, a silicon oxide layer or the like as described above.

Further, the stacked body LMsa in which a plurality of insulating layers NL and a plurality of insulating layers OL are alternately stacked one by one is formed above the upper source line DSLb. The insulating layer NL is, for example, a silicon nitride layer or the like, and functions as a sacrificial layer that is latterly replaced with a conductive material to become the word line WL or the selection gate line SGS.

As illustrated in FIG. 8B, in a partial region of the stacked body LMsa, the insulating layers NL and the insulating layers OL are processed in a step-like shape. Such processing can be performed by repeating slimming of a mask pattern such as a photoresist layer, and etching of insulating layer NL and the insulating layer OL of the stacked body LMsa a plurality of times.

More specifically, the mask pattern is formed on the top surface of the stacked body LMsa, and the insulating layer NL and the insulating layer OL in an exposed portion, for example, are both removed by etching for one layer. Further, the top surface of the stacked body LMsa is newly exposed by retreating the end of the mask pattern through processing such as oxygen plasma processing, and the insulating layer NL and the insulating layer OL are further both removed by etching for one layer. By repeating such processing a plurality of times, the above-described step-like shape is formed.

As illustrated in FIG. 8C, the insulating layer 51 covering the step portion and reaching the height of the top surface of the stacked body LMsa is formed. The insulating layer 51 is formed also in an outside region of the stacked body LMsa.

As illustrated in FIG. 8D, a plurality of memory holes MHa and a plurality of holes HLa extending in the stacking direction of the stacked body LMsa are formed, for example, collectively. The memory hole MHa is a portion that latterly becomes a lower structure of the pillar PL. The hole HLa is a portion that latterly becomes a lower structure of either of the columnar portions HRm and HRS.

The plurality of memory holes MHa is arranged in a region that latterly becomes the memory region MR, penetrates through the stacked body LMsa, the upper source line DSLb, and the intermediate sacrificial layer SCN, and reaches the lower source line DSLa. The plurality of holes HLa is arranged in a region that latterly becomes the step region SR, penetrates through the insulating layer 51, the stacked body LMsa, the upper source line DSLb, and the intermediate insulating layer SCO, and reaches the lower source line DSLa.

As illustrated in FIG. 8E, a sacrificial layer 26 such as an amorphous silicon layer or a CVD (chemical vapor deposition)-carbon layer is filled into these memory holes MHa and holes HLa.

The pillar PLc in which the sacrificial layer 26 is filled into the plurality of memory holes MHa is thereby formed in a region that latterly becomes the memory region MR. Further, a columnar portion HRc in which the sacrificial layer 26 is filled into the plurality of holes HLa is formed in a region that latterly becomes the step region SR.

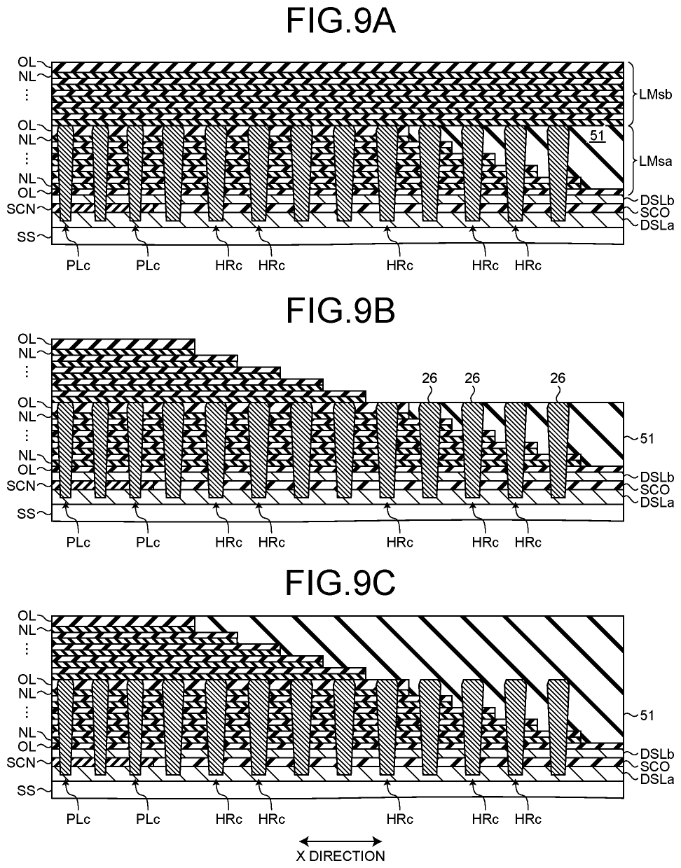

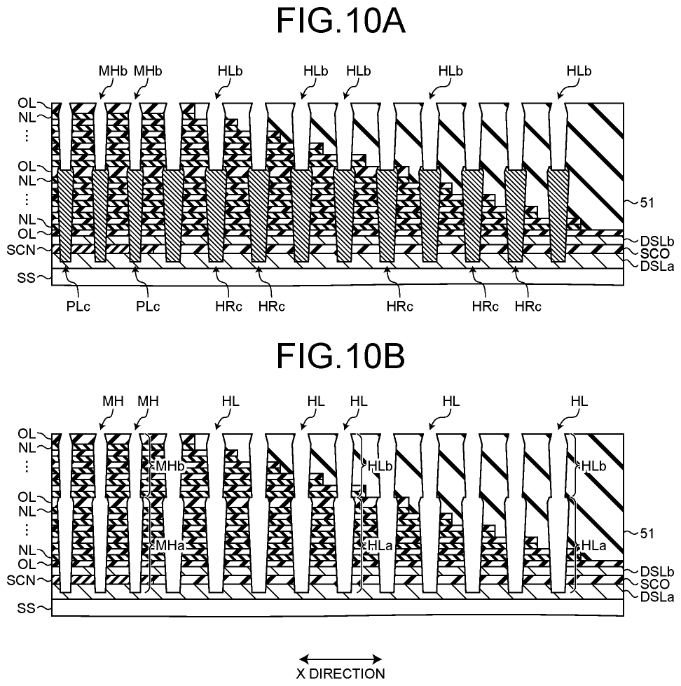

Next, FIGS. 9A to 10B illustrate a procedure of forming a stacked body LMsb being an upper layer portion of the stacked body LM before the word line WL is formed, and further forming various components on the stacked body LMsb.

Similarly to FIGS. 8A to 8E, FIGS. 9A to 10B are cross-sectional views along the X direction that illustrate regions latterly becoming the memory region MR and the step region SR.

As illustrated in FIG. 9A, the stacked body LMsb in which a plurality of insulating layers NL and a plurality of insulating layers OL are alternately stacked one by one, is formed so as to cover over the stacked body LMsa, and in the step portion, over the insulating layer 51. The sacrificial layer NL in the stacked body LMsb is latterly replaced with a conductive layer, and becomes the word line WL or the selection gate lines SGD.

As illustrated in FIG. 9B, in a partial region of the stacked body LMsb, the insulating layers NL and the insulating layers OL are processed in a step-like shape. Similarly to the above-described processing illustrated in FIG. 8B, such processing can be performed by repeating slimming of a mask pattern such as a photoresist layer, and etching of insulating layer NL and the insulating layer OL of the stacked body LMsb a plurality of times.

At this time, by bringing an uppermost step of the step portion formed in the stacked body LMsa, and a lowermost step of the step portion formed in the stacked body LMsb, closer to each other, these steps are formed in such a manner as to continuously extend from the lower layer side of the stacked body LMsa to the upper layer side of the stacked body LMsb. Further, by the stacked body LMsb on the insulating layer 51 that covers the step portion of the stacked body LMsa, being removed, the upper end of the columnar portion HRc formed in the step portion of the stacked body LMsa is exposed to the top surface of the insulating layer 51.

In addition, in a case where the sacrificial layer 26 filled into the columnar portion HRc is a CVD-carbon layer or the like, to prevent the sacrificial layer 26 from being removed at the time of slimming of the above-described mask pattern, the top surface of the columnar portion HRc is preliminarily protected by a silicon oxide layer or the like.

As illustrated in FIG. 9C, the insulating layer 51 is formed so as to cover the top surface of the insulating layer 51 from which the columnar portion HRc is exposed and a step portion newly formed in the stacked body LMsb, and to reach the height of the top surface of the stacked body LMsb. The insulating layer 51 is formed also in an outside region of the stacked bodies LMsa and LMsb.

As illustrated in FIG. 10A, a plurality of memory holes MHb and a plurality of holes HLb extending in the stacking direction at the height position of the stacked body LMsb are formed, for example, collectively. The memory hole MHb is a portion that latterly becomes an upper structure of the pillar PL. The hole HLb is a portion that latterly becomes an upper structure of either of the columnar portions HRm and HRS.

The plurality of memory holes MHb is arranged in a region that latterly becomes the memory region MR, penetrates through the stacked body LMsb, and reaches the upper end of the pillar PLc formed in the stacked body LMsa.

The plurality of holes HLb are arranged at positions overlapping the step portions of the stacked bodies LMsa and LMsb in the stacking direction, penetrates through the insulating layer 51 and the stacked body LMsb, and respectively reaches the upper ends of the columnar portions HRc formed in the stacked body LMsa.

As illustrated in FIG. 10B, the sacrificial layer 26 is removed from the pillar PLc and the columnar portion HRc at the bottoms of the memory holes MHb and the holes HLb.

The memory holes MHa are respectively opened at the bottoms of the plurality of memory holes MHb, and thereby a plurality of memory holes MH penetrating through the stacked bodies LMsb and LMsa, the upper source line DSLb, and the intermediate sacrificial layer SCN, and reaching the lower source line DSLa is formed. Further, the holes HLa are respectively opened at the bottoms of the plurality of holes HLb, and thereby a plurality of holes HL penetrating through the insulating layer 51, the stacked bodies LMsb and LMsa, the upper source line DSLb, and the intermediate insulating layer SCO, and reaching the lower source line DSLa is formed.

Note that, in a case where the sacrificial layer 26 filled into the pillar PLc and the columnar portion HRc is a CVD-carbon layer or the like, when the mask pattern or the like used in the above-described processing in FIG. 10A is removed by ashing or the like that uses oxygen plasma, the sacrificial layer 26 can be also removed from the pillar PLC and the columnar portion HRc collectively.

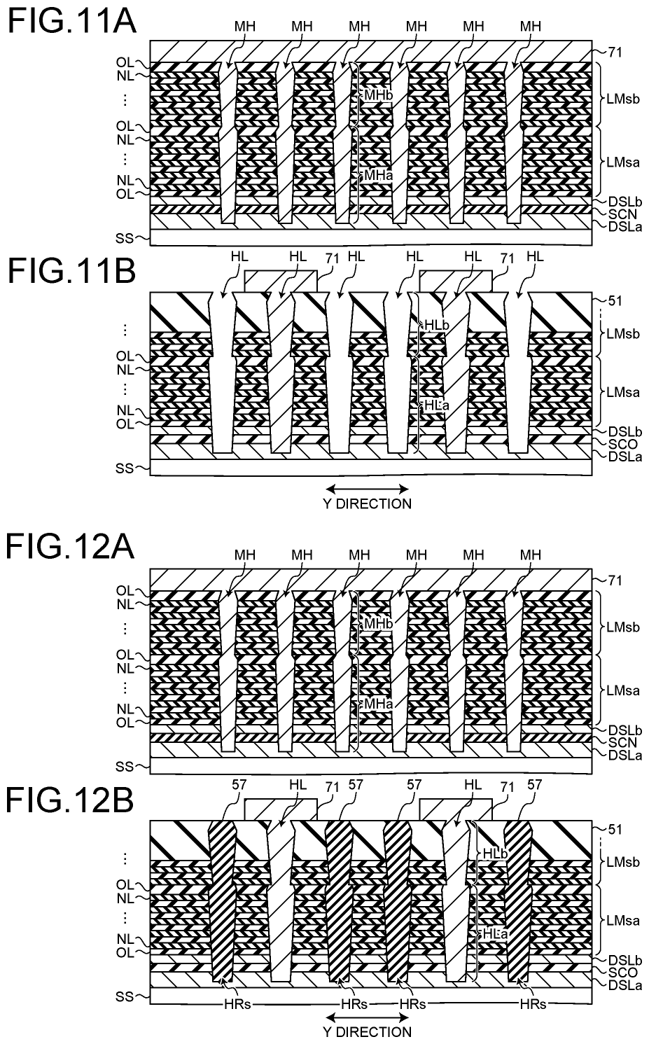

Next, FIGS. 11A to 12B illustrate a procedure of forming the columnar portion HRs. FIGS. 11A and 12A of FIGS. 11A to 12B are cross-sectional views along the Y direction that illustrate a region that latterly becomes the memory region MR. More specifically, FIGS. 11A and 12A are cross-sectional views corresponding to the cross section illustrated in FIG. 2A as above described. FIGS. 11B and 12B of FIGS. 11A to 12B are cross-sectional views along the Y direction that illustrate a region that latterly becomes the step portion SP in the step region SR. More specifically, FIGS. 11B and 12B are cross-sectional views corresponding to the cross section illustrated in FIG. 3B as above described.

As illustrated in FIG. 11A, a plurality of memory holes MH is covered with a mask layer 71 such as a photoresist layer. That is, the entire region that latterly becomes the memory region MR is covered. Further, among a region that latterly becomes the step portion SP, the entire region in which the selection gate lines SGD are to be processed in a step-like shape, which is not illustrated in the drawing, is also covered with the sheet-like mask layer 71.

As illustrated in FIG. 11B, in a portion in which the word line WL and the selection gate line SGS are to be processed in a step-like shape among a region that latterly becomes the step portion SP, among the plurality of holes HL, the holes HL belonging to arrays latterly including a point proximal to the contact CC, and the holes HL belonging to arrays neighboring the plate-like contact LI are left as-is, and the holes HL belonging to the other arrays are covered with the mask layer 71.

More specifically, among the holes HL on six arrays illustrated in FIG. 11B, the holes HL belonging to the arrays arranged at both ends in the left-right direction of the paper neighbor a portion in which the plate-like contact LI is latterly formed. Further, the holes HL belonging to two arrays at the center of the paper are proximal to a portion in which the contact CC is latterly formed.

Accordingly, in the example illustrated in FIG. 11B, the other holes HL on the second array from the left and the second array from the right in the left-right direction of the paper are covered with the mask layer 71. That is, the mask layer 71 illustrated in FIG. 11B extends like a strip in a depth direction of the paper.

As described above, in the semiconductor memory device 1, in a case where a predetermined array of a plurality of arrays of the columnar portions HRs and HRm includes a point proximal to the contact CC, the columnar portions HRs are arranged over the entire of the array. With this configuration, as compared with a case where the columnar portions HRs are arranged at very limited points around the contact CC, for example, the mask layer 71 can be arranged like a strip, for example, without forming the mask layer 71 highly precisely, and the difficulty of the formation process of the columnar portion HRs can be lowered.

As illustrated in FIG. 12B, the columnar portions HRs are formed by filling the insulating layer 57 such as a silicon oxide layer into the holes HL at the left and right both ends and the central portion, exposed from the mask layer 71, of the paper.

After that, the mask layer 71 is removed using oxygen plasma or the like. The plurality of memory holes MH and the remaining holes HL are thereby opened again.

In addition, in the above-described processing, among a region that latterly becomes the step portion SPd, the entire region in which the selection gate lines SGD are to be processed in a step-like shape is also covered with the sheet-like mask layer 71, and the plurality of holes HL is left as-is, which is not illustrated in the drawing. On the other hand, in a region in which the word line WL and the selection gate line SGS are processed in a step-like shape among a region that latterly becomes the step portion SPd, the holes HL belonging to other arrays excluding an array latterly neighboring the plate-like contact LI, among a plurality of holes HL, are left by being covered with the mask layer 71.

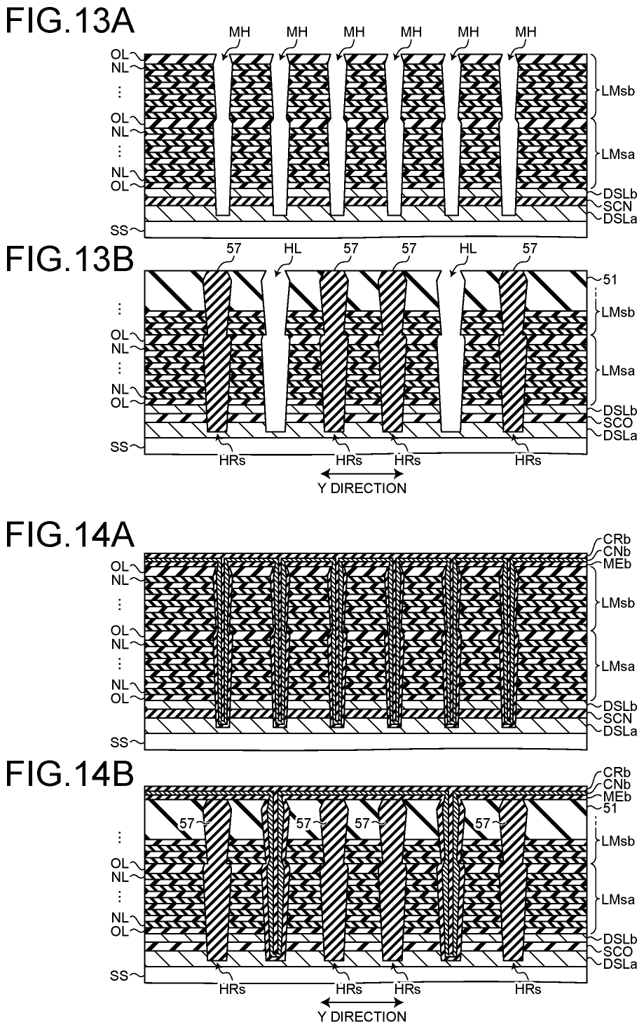

Next, FIGS. 13A to 18B illustrate a procedure of forming a multilayer structure in the memory holes MH and the remaining holes HL.

FIGS. 13A, 14A, 15A, 16A, 17A, and 18A of FIGS. 13A to 18B are cross-sectional views along the Y direction that illustrate a region that latterly becomes the memory region MR, similarly to FIGS. 11A and 12A of FIGS. 11A to 12B described above, and FIGS. 13B, 14B, 15B, 16B, 17B, and 18B of FIGS. 13A to 18B are cross-sectional views along the Y direction that illustrate a region that latterly becomes the step portion SP in the step region SR, similarly to FIGS. 11B and 12B of FIGS. 11A to 12B described above.

As illustrated in FIGS. 13A and 14A, in the region that latterly becomes a memory region MR, a multilayered insulating layer MEb, a semiconductor layer CNb, and an insulating layer CRb are formed in this order in the memory holes MH. The multilayered insulating layer MEb and the semiconductor layer CNb are thereby arranged on the side surfaces of the memory holes MH, and the bottom surface on which the lower source line DSLa is exposed, and the insulating layer CRb is filled into the central portions of the memory holes MH.

The multilayered insulating layer MEb is an insulating layer that latterly becomes the memory layer ME, and has a multilayer structure. The semiconductor layer CNb is a layer that latterly becomes the channel layer CN. The insulating layer CRb is a silicon oxide layer or the like that latterly becomes the core layer CR.

The multilayered insulating layer MEb, the semiconductor layer CNb, and the insulating layer CRb are formed in this order also on the top surface of the stacked body LMsb.

As illustrated in FIGS. 13B and 14B, also in a region that latterly becomes the step portion SP, through the processing in FIGS. 13A and 14A, the multilayered insulating layer MEb and the semiconductor layer CNb are formed on the side surfaces of the holes HL, and the bottom surface on which the lower source line DSLa is exposed, and the insulating layer CRb is filled into the central portions of the holes HL.

Also in a region that latterly becomes the step portion SP, the multilayered insulating layer MEb, the semiconductor layer CNb, and the insulating layer CRb are formed in this order also on the top surface of the insulating layer 51.

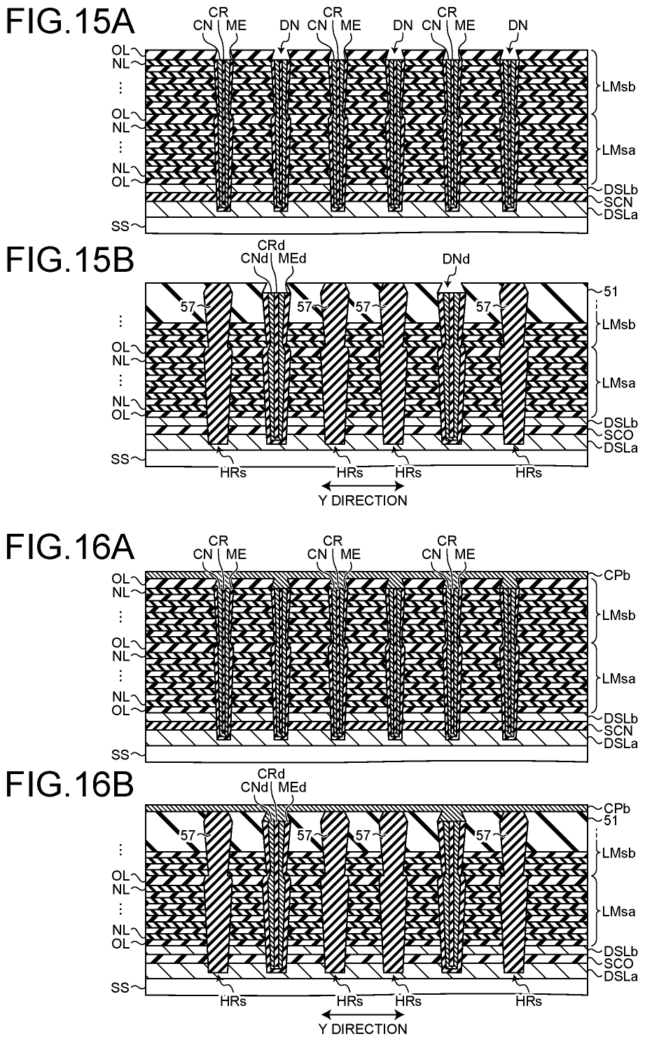

As illustrated in FIG. 15A, in a region that latterly becomes the memory region MR, the insulating layer CRb, the semiconductor layer CNb, and the multilayered insulating layer MEb are removed from the top surface of the stacked body LMsb by sequentially performing etch back, and recesses DN are formed at the upper ends of the memory holes MH.

The memory layer ME, the channel layer CN, and the core layer CR are thereby formed in the memory holes MH in order from the outer periphery side.

As illustrated in FIG. 15B, also in a region that latterly becomes the step portion SP, through the processing in FIG. 15A, the insulating layer CRb, the semiconductor layer CNb, and the multilayered insulating layer MEb are sequentially removed from the top surface of the insulating layer 51, and recesses DNd are formed at the upper ends of the holes HL.

The dummy layers MEd, CNd, and CRd are thereby formed in the holes HL in order from the outer periphery side.

In addition, at the time of etch back of the insulating layer CRb, the semiconductor layer CNb, and the multilayered insulating layer MEb, the top surface of the columnar portion HRs into which the insulating layer 57 or the like of the same type as the multilayered insulating layer MEb and the insulating layer CRb is filled may be protected by a mask layer (not illustrated) or the like.

As illustrated in FIG. 16A, in a region that latterly becomes the memory region MR, a semiconductor layer CPb is formed in the recesses DN at the upper ends of the memory holes MH. The semiconductor layer CPb is a layer that latterly becomes the cap layer CP. The semiconductor layer CPb is formed also on the top surface of the stacked body LMsb.

As illustrated in FIG. 16B, also in a region that latterly becomes the step portion SP, through the processing in FIG. 16A, the semiconductor layer CPb is filled into the recesses DNd at the upper ends of the holes HL, and the top surface of the insulating layer 51 is covered with the semiconductor layer CPb.

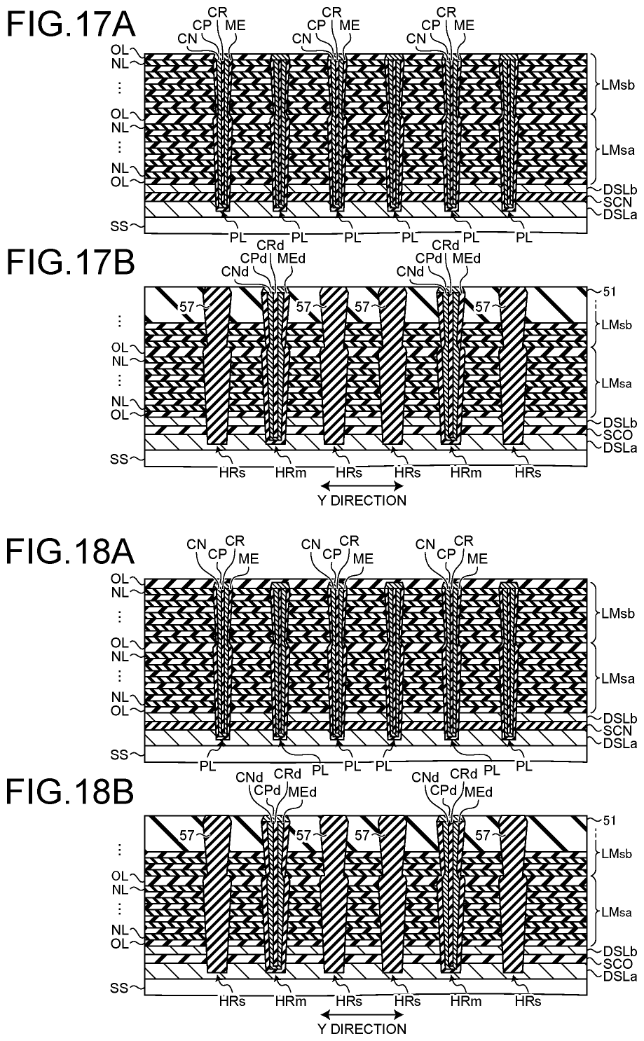

As illustrated in FIGS. 17A and 18A, in a region that latterly becomes the memory region MR, the semiconductor layer CPb on the top surface of the stacked body LMsb is removed by CMP (chemical mechanical polishing) or the like, and the cap layer CP is formed on the upper ends of the memory holes MH. The insulating layer OL is further stacked on the uppermost layer of the stacked body LMsb thinned by the CMP or the like.

The pillar PL in which the cap layer CP is buried in the uppermost insulating layer OL is thereby formed. Note that, at this time point, the memory layer ME covers the entire side wall of the pillar PL, and a state in which a part of the side surface of the channel layer CN is exposed from the memory layer ME has not been caused.

As illustrated in FIGS. 17B and 18B, also in a region that latterly becomes the step portion SP, through the processing in FIGS. 17A and 18A, the dummy layers CPd are formed at the upper ends, and the columnar portions HRm are formed.

In addition, the columnar portion HRm is formed as a dummy configuration serving as a support structure during replacement processing to be described later, and does not contribute to the function of the semiconductor memory device 1. Accordingly, the columnar portion HRm needs not include the dummy layer CPd, and the processing in FIG. 16B needs not be performed on the columnar portion HRm. In this case, the recesses DNd at the upper end of the holes HL can be backfilled with an insulating layer or the like, for example.

Further, the above-described processing in FIGS. 13A to 18B is performed also on a plurality of holes HL in a region that latterly becomes the step portion SPd. With this configuration, also in a region that latterly becomes the step portion SPd, the columnar portions HRm belonging to a plurality of arrays excluding an array latterly neighboring the plate-like contact LI are formed.

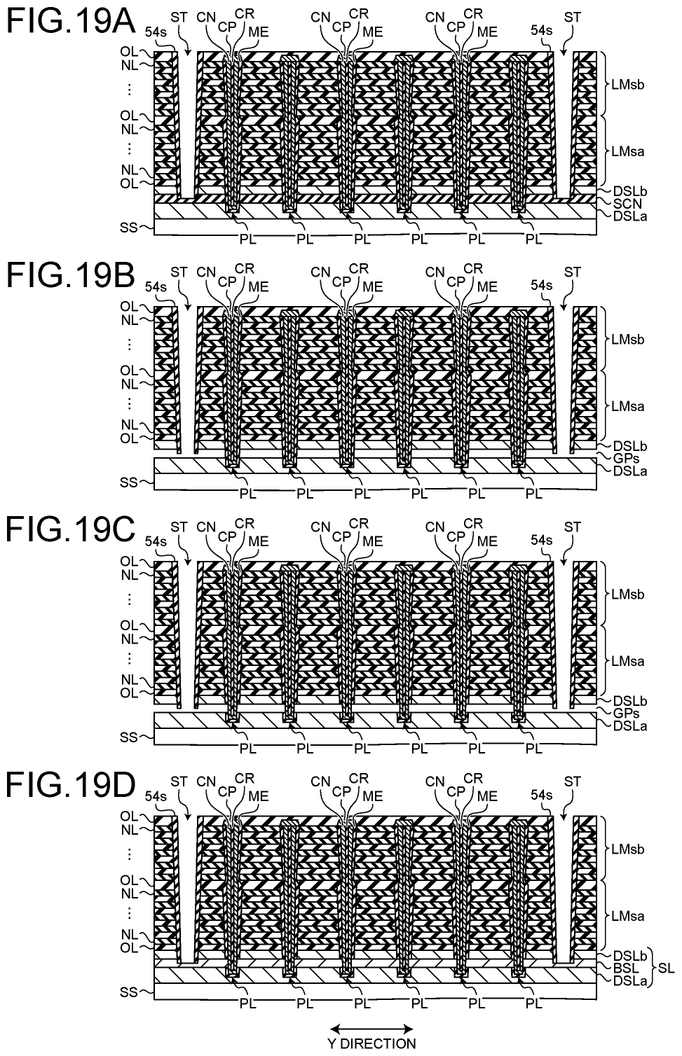

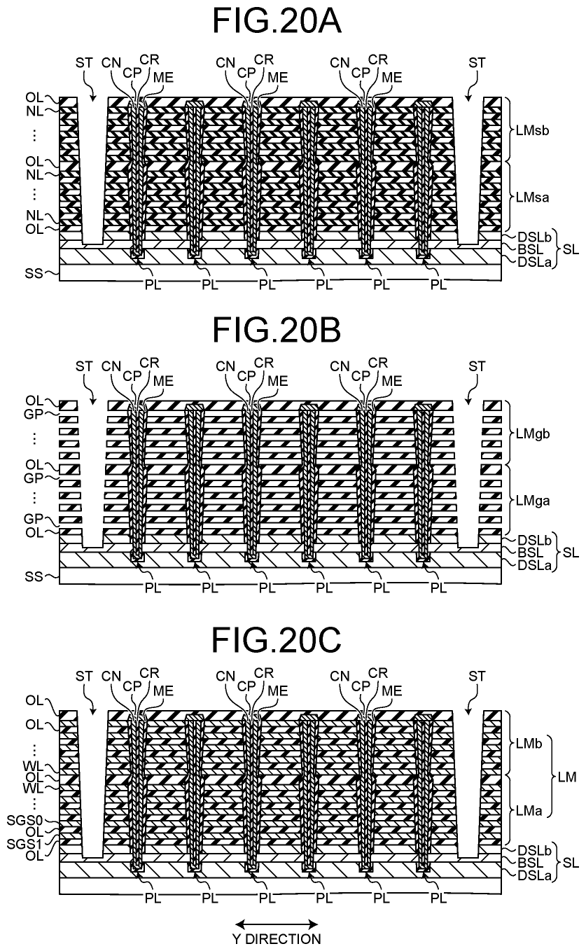

Next, FIGS. 19A to 20C illustrate a procedure of forming the source line SL and the word line WL.

FIGS. 19A to 20C are cross-sectional views along the Y direction that illustrates a region that latterly becomes the memory region MR, similarly to FIGS. 13A, 14A, 15A, 16A, 17A, and 18A of FIGS. 13A to 18B described above.

As illustrated in FIG. 19A, a slit ST penetrating through the stacked bodies LMsb and LMsa, and the upper source line DSLb, and reaching the intermediate sacrificial layer SCN is formed. Further, an insulating layer 54s is formed on the side walls of the slit ST that face each other in the Y direction.

The slit ST has a YZ cross-section of a tapered shape or a bowing shape, and extends in the stacked bodies LMsa and LMsb in the direction along the X direction. Accordingly, in the step region SR (not illustrated), the lower end of the slit ST reaches the intermediate insulating layer SCO.

At this time, due to a difference in etch resistance between the stacked bodies LMsa and LMsb in which a plurality of insulating layers NL and OL is alternately stacked, and the insulating layer 51 being a single body of a silicon oxide layer or the like, the degree of the tapered shape or the bowing shape of the slit ST becomes more prominent in the step region SR covered with the insulating layer 51.

Further, as getting closer to the step portion on the lower layer side from the upper layer side of the step region SR, a distance by which the slit ST extends in the insulating layer 51 in the stacking direction of the stacked bodies LMsa and LMsb is longer. Accordingly, as getting closer to the step portion on the lower layer side from the upper layer side, the degree of the tapered shape or the bowing shape of the slit ST becomes higher.

As illustrated in FIG. 19B, the intermediate sacrificial layer SCN sandwiched between the lower source line DSLa and the upper source line DSLb is removed by flowing removal liquid of the intermediate sacrificial layer SCN such as hot phosphoric acid, for example, via the slit ST of which the side walls are protected by the insulating layer 54s.

A gap layer GPs is thereby formed between the lower source line DSLa and the upper source line DSLb. Further, a part of the memory layer ME in the outer periphery portion of the pillar PL is exposed to the inside of the gap layer GPs.

At this time, because the side walls of the slit ST are protected by the insulating layer 54s, the insulating layers NL in the stacked bodies LMsa and LMsb are prevented from being removed. Further, in the step region SR (not illustrated), the intermediate sacrificial layer SCN is not provided between the lower source line DSLa and the upper source line DSLb, and the gap layer GPs is not formed.

As illustrated in FIG. 19C, by appropriately flowing several types of chemical liquids into the gap layer GPs via the slit ST, the block insulating layer BK, the charge accumulation layer CT, and the tunnel insulating layer TN (refer to FIGS. 2B and 2C) of the memory layer ME exposed to the inside of the gap layer GPs are sequentially removed. The memory layer ME is thereby removed from a part of the side walls of the pillar PL, and a part of the channel layer CN inside of the memory layer ME is exposed to the inside of the gap layer GPs.

As illustrated in FIG. 19D, from the slit ST of which the side walls are protected by the insulating layer 54s, raw material gas such as amorphous silicon, for example, is injected, and amorphous silicon or the like is filled into the gap layer GPs. Further, by heat-treating the support substrate SS, amorphous silicon filled into the gap layer GPs, is polycrystallized to form the intermediate source line BSL containing polysilicon or the like.

A part of the channel layer CN of the pillar PL is thereby connected with the source line SL on the side surface via the intermediate source line BSL.

At this time, in the step region SR (not illustrated), the gap layer GPs is not formed between the lower source line DSLa and the upper source line DSLb. Thus, for example, the dummy layer MEd of the columnar portion HRm is not removed, and further, the formation of the intermediate source line BSL is not performed, either.

The columnar portion HRm being a dummy configuration preferably does not have electric conduction with the source line SL. As described above, in the step region SR excluding the memory region MR, by arranging the intermediate insulating layer Sco between the lower source line DSLa and the upper source line DSLb in place of the intermediate sacrificial layer SCN, conduction between the columnar portion HRm and the source line SL is prevented.

As illustrated in FIG. 20A, the insulating layer 54s on the side walls of the slit ST is once removed.

As illustrated in FIG. 20B, by flowing removal liquid of the insulating layer NL such as hot phosphoric acid, for example, from the slit ST into the stacked bodies LMsa and LMsb, the insulating layers NL in the stacked bodies LMsa and LMsb are removed. The stacked bodies LMga and LMgb including a plurality of gap layers GP from which the insulating layers NL between the insulating layers OL are removed are thereby formed.

The stacked bodies LMga and LMgb including a plurality of gap layers GP have a fragile structure. In a region that latterly becomes the memory region MR, the plurality of pillars PL supports such fragile stacked bodies LMga and LMgb. On the other hand, in a region that latterly becomes the step region SR, a plurality of columnar portions HRm and HRs supports these stacked bodies LMga and LMgb.

By such support structures of the pillars PL and the columnar portions HRm and HRs, the remaining insulating layer OL is prevented from warping, and the stacked bodies LMga and LMgb are prevented from becoming distorted or collapsing.

As illustrated in FIG. 20C, the plurality of word lines WL and the like are formed by injecting raw material gas of a conductive material such as tungsten or molybdenum, for example, into the stacked bodies LMga and LMgb from the slit ST, and filling the conductive material into the gap layers GP in the stacked bodies LMga and LMgb. The stacked body LM including the stacked bodies LMa and LMb in which the plurality of word lines WL or the like and a plurality of insulating layers OL are alternately stacked one by one is thereby formed.

As described above, processing of forming the intermediate source line BSL from the intermediate sacrificial layer SCN, and processing of forming the word line WL from the insulating layer NL will also be referred to as the replacement processing.

After that, the plate-like contact LI is formed by forming the insulating layer 54 on the side walls of the slit ST, and filling the conductive layer 24 into the insulating layer 54. Note that the plate-like member may be formed by filling the insulating layer 54 or the like without forming the conductive layer 24 in the slit ST.

Further, by forming a groove penetrating through the uppermost layer of the stacked body LMb and the second conductive layer from the top, and filling the insulating layer 56 into the groove, the separating layer SHE that segments these conductive layers into the patterns of the selection gate lines SGD is formed.

Further, a plurality of contact holes penetrating through the insulating layer 51, and respectively reaching the word line WL and the selection gate lines SGD and SGS that form each step of the step portion SP, is formed collectively, and then, the insulating layer 55 and the conductive layer 25 are formed in the contact holes. The contacts CC respectively connected to the plurality of word lines WL and the selection gate lines SGD and SGS are thereby formed.

Subsequently, the insulating layer 52 is formed on the top surface of the insulating layer 51 that covers the top surface of the stacked body LM and the step region SR, and the plug VO penetrating through the insulating layer 52 and connected to the contact CC is formed. Further, the plug CH penetrating through the insulating layer 52 and connected to the pillar PL is formed. Furthermore, the insulating layer 53 is formed on the insulating layer 52, and the upper layer wire MX and the bit-line BL, and the like connected to the plugs VO and CH are formed. Further, an electrode pad or the like for having electric conduction with the peripheral circuit CBA is formed on the top surface of the insulating layer 53.

Note that, by using a dual damascene method or the like, for example, the plugs VO and CH, the upper layer wire MX, and the bit-line BL, and the like may be collectively formed.

Further, on the semiconductor substrate SB different from the support substrate SS on which the stacked body LM is formed, the peripheral circuit CBA is formed and covered with the insulating layer 40. In the insulating layer 40, a contact, a via, a wire, and the like for drawing the peripheral circuit CBA to the surface of the insulating layer 40 are formed, and connected with an electrode pad and the like formed on the top surface of the insulating layer 40.

Subsequently, the support substrate SS and the semiconductor substrate SB are bonded via the insulating layers 50 and 40 respectively included in these substrates SS and SB, and electrode pads in the insulating layers 50 and 40 are connected. After that, by removing the support substrate SS, the source line SL is exposed, and the electrode film EL is connected via the insulating layer 60 in which the plug PG is formed.

As described above, the semiconductor memory device 1 of the first embodiment is manufactured.

In a manufacturing process of a semiconductor memory device such as a three-dimensional nonvolatile memory, sometimes by replacing a sacrificial layer in a stacked body with a conductive layer, a stacked body in which a conductive layer and an insulating layer are stacked is formed. In this case, to support a fragile stacked body including a plurality of gap layers, during the replacement processing, for example, a columnar portion is arranged in a step region. The columnar portion has a structure in which an insulating layer such as a silicon oxide layer is filled into a hole penetrating through the stacked body, for example.

However, in a case where the columnar portion is formed using an insulating layer or the like, by thermal processing in a subsequent manufacturing process, the insulating layer included in the columnar portion sometimes contracts. In this case, by the contraction of a plurality of columnar portions, the entire region in which these columnar portions are arranged sometimes subducts in the stacking direction of the stacked body as compared with other regions such as a memory region supported by pillars. That is to say, the top surface of a semiconductor memory device in the process of manufacturing may have unevenness.

Consequently, for example, in processing or the like that uses a lithography technology to be performed in a region where subduction occurs, a focus error may occur and this error may cause a patterning error. Further, for example, in processing of polishing and removing a conductive material buried in a hole, a groove, or the like that is formed in an insulating layer in an upper part of a stacked body, from the top surface on the outside of the hole or the groove, or the like, unpolished conductive material sometimes remains in a region where subduction has occurred.

In view of the foregoing, for example, it is considered to form a columnar portion using a stiff material with a Young's modulus higher than that of a silicon oxide layer or the like. In this case, for example, by making the layer structure of the columnar portions consistent with the layer structure of pillars including a channel layer and the like that have high Young's modulus, it is possible to collectively form the columnar portions and the pillars, which is convenient.

However, in a case where the layer structures of the columnar portions and the pillars are made the same, there arises a problem of decrease in withstand voltage between a plurality of word lines that is attributed to contact between a slit or a contact hole and the columnar portions.

Specifically, a formation condition of a contact hole includes a low etching selectivity to a nitride layer, and if a columnar portion includes a nitride layer or the like that corresponds to a charge accumulation layer, by the contact hole contacting, the nitride layer of the columnar portion might be removed. After that, when a conductive layer is filled into the contact hole, the conductive layer is filled also into an air gap in the columnar portion that is generated by the removal of the nitride layer, and withstand voltage sometimes becomes insufficient among a plurality of word lines.

Further, when a slit for performing the replacement processing of the stacked body is formed, if a columnar portion includes a nitride layer or the like that corresponds to a charge accumulation layer, there arises a concern that the slit and the columnar portion contact, and the nitride layer of the columnar portion is exposed to the inside of the slit. In this case, when the replacement processing is performed via the slit, the nitride layer of the columnar portion is also replaced with a conductive layer via the exposed portion, and similarly to the foregoing, withstand voltage might become insufficient among a plurality of word lines.

According to the semiconductor memory device 1 of the first embodiment, at least a part of the plurality of columnar portions HRs belongs to an array at least partially overlapping an array position of the plurality of contacts CC in the X direction among a plurality of arrays of the columnar portions HRm and HRs. A part of the plurality of columnar portions HRm belongs to an array away in the Y direction from the array positions of the plurality of contacts CC.

In this manner, by arranging the columnar portion HRs being a single body of the insulating layer 57 at a position with high contact risk with the contact CC, it is possible to arrange the columnar portions HRs at high density while permitting contact with the contacts CC, and sufficiently support the stacked bodies LMga and LMgb in the replacement processing.

On the other hand, by arranging the columnar portion HRm including the dummy layer CNd corresponding to a channel layer with high Young's modulus, at a position with low contact risk with the contacts CC, in subsequent processing, subduction of the stacked body LM can be prevented.

According to the semiconductor memory device 1 of the first embodiment, a part of the plurality of columnar portions HRs belongs also to an array neighboring the array position of the plurality of contacts CC in the Y direction among the plurality of arrays of the columnar portions HRm and HRs. In this manner, the array neighboring the contacts CC also includes a position with relatively high contact risk with the contacts CC. By arranging the columnar portions HRs also on the array neighboring the contacts CC, it is possible to further suppress a negative effect attributed to contact with the contacts CC.

According to the semiconductor memory device 1 of the first embodiment, another part of the plurality of columnar portions HRs belongs to an array neighboring the plate-like contact LI in the Y direction among the plurality of arrays of the columnar portions HRm and HRS. In this manner, by arranging the columnar portion HRs being a single body of the insulating layer 57 at a position with high contact risk with the plate-like contact LI, it is possible to arrange the columnar portions HRs at high density while permitting contact with the plate-like contact LI, and sufficiently support the stacked bodies LMga and LMgb in the replacement processing.

According to the semiconductor memory device 1 of the first embodiment, at least a part of the plurality of columnar portions HRs among the plurality of columnar portions HRm and HRs is arranged in the step portion SP arranged at one end in the X direction of the stacked body LM. In the step portion SPd that is arranged at another end in the X direction of the stacked body LM, and faces the above-described step portion SP in the X direction, at least a part of the plurality of columnar portions HRm is arranged in a dispersed manner on a plurality of arrays.

In this manner, in the semiconductor memory device 1 employing a one-sided drawing method in which the contact CC is arranged in the step portion SP on the X direction one side in the same block region BLK, the columnar portion HRm can be mainly arranged in the step portion SPd on the other side in the X direction in which the contact CC is not arranged. The subduction of the stacked body LM can be thereby further prevented.

According to the semiconductor memory device 1 of the first embodiment, in the step portions SP and SPd, another part of the plurality of columnar portions HRs among the plurality of arrays of the columnar portions HRm and HRs belongs to an array neighboring in the Y direction each of the plate-like contacts LI arranged in the Y direction, among the plurality of arrays of the columnar portions HRm and HRs. Also in the step portion SPd in which the contact CC is not arranged, it is accordingly possible to arrange the columnar portions HRs at high density while permitting contact with the plate-like contact LI, and sufficiently support the stacked bodies LMga and LMgb in the replacement processing.

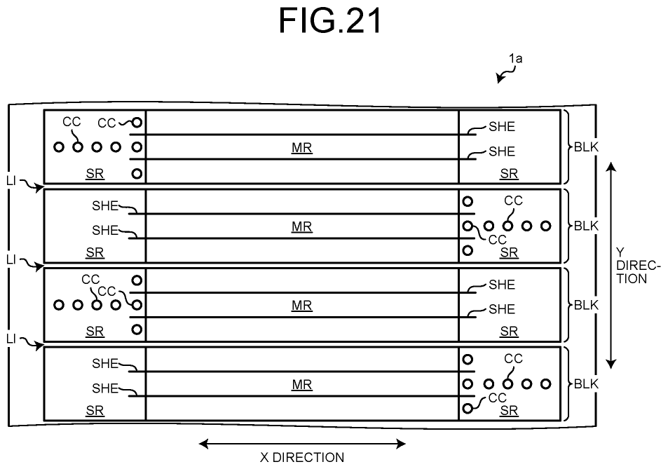

Note that, in the above-described first embodiment, in the method of drawing the plurality of word lines WL and the like on one side, in the step region SR on the X direction one side, the step portions SP and SPd are alternately arranged in the Y direction for every two block regions BLK. However, in the one-sided drawing method of the word line WL and the like, it is sufficient that the step portion SP is arranged on the X direction one side in the same block region BLK, and the arrangement order of the step portions SP and SPd is not limited to the above-described order. FIG. 21 illustrates another example of the arrangement of the step portions SP and SPd.

FIG. 21 is a schematic plan view illustrating the layout of a semiconductor memory device 1a according to a modified example of the first embodiment.

In the example illustrated in FIG. 21, the step portions SP and SPd included in the semiconductor memory device 1a are alternately arranged in the Y direction for every one block region BLK in the step region SR on the X direction one side. Also in such arrangement, the semiconductor memory device 1a can be caused to function using a method of drawing the plurality of word lines WL and the like on one side.

Further, in the above-described first embodiment, the stacked body LM having a two-tier structure in which the two stacked bodies LMa and LMb are stacked up and down is included. However, the configuration of the stacked body is not limited to the two-tier structure, and may be a one-tier structure or a structure including three or more tiers.

Further, in the above-described first embodiment, the pillar PL is connected with the source line SL on the side surface of the channel layer CN, but the configuration of the pillar PL is not limited to this. For example, the pillar may be configured to be connected to the source line at the lower end of the channel layer by removing the memory layer on the pillar bottom surface.

Further, in the above-described first embodiment, the peripheral circuit CBA is arranged above the stacked body LM. However, the peripheral circuit may be arranged below the stacked body or in the same layer as the stacked body.

In a case where a peripheral circuit is arranged below a stacked body, for example, a source line and a stacked body can be formed on an insulating layer of a semiconductor substrate including a peripheral circuit covered with an insulating layer. In a case where a peripheral circuit is arranged in the same layer as a stacked body, a stacked body can be formed at a position different from that of a peripheral circuit on a semiconductor substrate on which the peripheral circuit is formed.

### Second Embodiment

Hereinafter, the second embodiment will be described in detail with reference to the drawings. A semiconductor memory device of the second embodiment differs from that of the above-described first embodiment in arrangement of a step region in the stacked body LM.

In the drawings to be described below, the components similarly to those in the above-described first embodiment are assigned the same reference numerals, and the description thereof will be omitted in some cases.

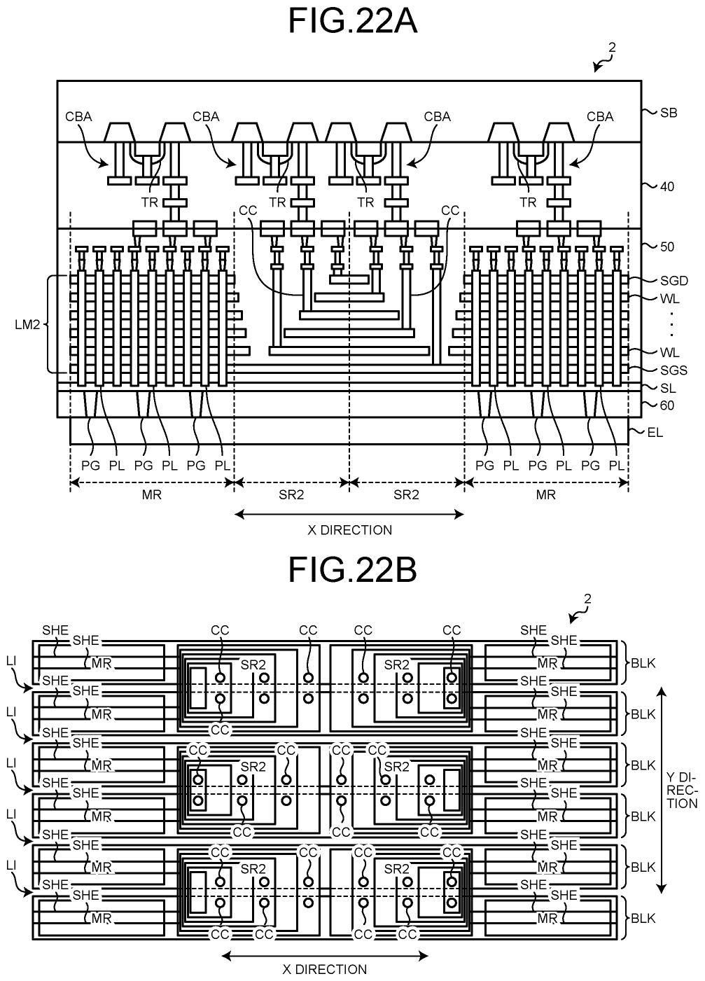

FIGS. 22A and 22B are diagrams illustrating a schematic configuration example of a semiconductor memory device 2 according to the second embodiment. More specifically, FIG. 22A is a cross-sectional view along an X direction that illustrates the semiconductor memory device 2, and FIG. 22B is a schematic plan view illustrating the layout of the semiconductor memory device 2. Note that hatching is omitted in FIG. 22A in consideration of visibility of the drawing. Further, in FIG. 22A, some of upper layer wires and the like are omitted.

As illustrated in FIG. 22A, similarly to the above-described first embodiment, the semiconductor memory device 2 also includes, in order from a lower side of the paper, an electrode film EL, a source line SL, one or more selection gate lines SGS, a plurality of word lines WL, one or more selection gate lines SGD, and a semiconductor substrate SB provided with a peripheral circuit CBA.

As illustrated in FIGS. 22A and 22B, a plurality of step regions SR2 is arranged aligned one another in the X direction at the central portion in the X direction of the plurality of word lines WL, and memory regions MR are respectively arranged at both ends in the X direction of the plurality of word lines WL. The memory region MR and the step regions SR2 are divided into a plurality of block regions BLK by a plurality of plate-like contacts LI penetrating through the plurality of word lines WL, and extending in a direction along the X direction.

Further, a plurality of separating layers SHE penetrating through the selection gate lines SGD and extending in a direction along the X direction is arranged between the plate-like contacts LI neighboring in the Y direction. The plurality of separating layers SHE extends over the entire memory region MR in the direction along the X direction, and reaches one end of the step region SR2 positioned at the middle of a stacked body LM2 in the X direction, that is closer to the memory region MR.

A plurality of pillars PL penetrating through the word lines WL and the selection gate lines SGD and SGS in the stacking direction is arranged in the memory region MR. The plurality of memory cells is formed at intersections between the pillar PL and the word lines WL. The semiconductor memory device 2 is thereby formed as a three-dimensional nonvolatile memory in which memory cells are three-dimensionally arranged in the memory region MR, for example.

One step region SR2 includes a step portion in which the plurality of word lines WL is dug down in the stacking direction in a shape also called a mortar shape, a valley shape, or a canyon shape, and is divided by the plate-like contact LI near the center in the Y direction. That is to say, one step region SR2 having the mortar shape is arranged over two block regions BLK across the plate-like contact LI.

In the step region SR2, each step of the step portion forms each side of the mortar shape that lowers like steps, from both sides in the X direction and the Y direction toward the bottom surface.

Each layer of the word line WL and the like that forms each step of the step portion maintains electric conduction between the X direction both sides across the step region SR2 via a portion of the step region SR2 on the Y direction one side. In mortar-shaped step portions that are arranged on one side and another side in the X direction, and face each other in the X direction, the contacts CC respectively connecting to the plurality of word lines WL and the like are arranged on a side separated from the memory region MR. At this time, the plurality of contacts CC is respectively connected to the word lines WL and the like in different layers of these step portions in the plurality of step regions SR2 arranged in the X direction one another, for example.

That is to say, the contacts CC may be connected, for example, to the first, third, and fifth word lines WL from the uppermost layer in a step portion included in one of the plurality of step regions SR2 aligned one another in the X direction, and connected, for example, to the second, fourth, and sixth word lines WL from the uppermost layer in a step portion included in another one of the plurality of step regions SR2 aligned one another in the X direction. Thus, the configuration is not limited to the example in FIG. 22A, and these step portions may have a configuration in which one step is formed by the word lines WL or the like on two layers, and the word line WL or the like to which the contact CC is connected mainly forms a terrace surface, for example.

From these contacts CC, a writing voltage, a readout voltage, and the like are applied to memory cells in the memory regions MR on both sides of the X direction, via the word lines WL at the same height position as the memory cells.

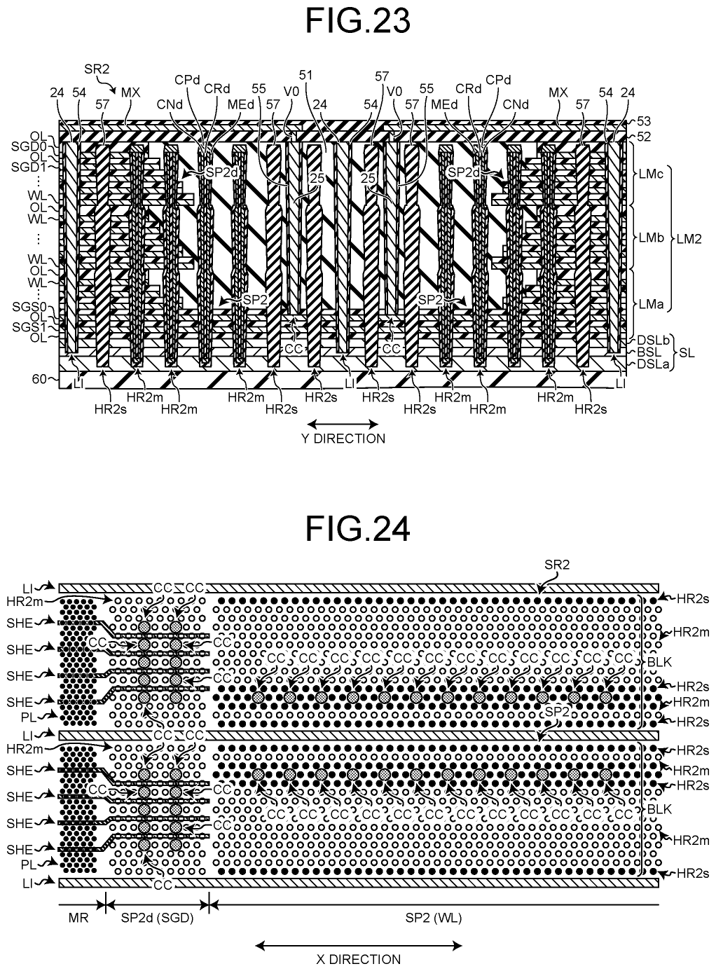

Next, a detailed configuration example of the semiconductor memory device 2 will be described with reference to FIG. 23.

FIG. 23 is a cross-sectional view along the Y direction that illustrates an example of a configuration of the step region SR2 included in the semiconductor memory device 2 according to the second embodiment. In FIG. 23, the structure existing below the insulating layer 60 and the structure existing above the insulating layer 53 are omitted.

Further, FIG. 23 illustrates an example in which the semiconductor memory device 2 includes the stacked body LM2 having three-tier structure. That is, in the example in FIG. 23, the stacked body LM2 of the semiconductor memory device 2 includes stacked bodies LMa, LMb, and LMc. The stacked body LMa is arranged above the source line SL, and includes one or more selection gate line SGS and the plurality of word lines WL. The stacked body LMb is arranged on the stacked body LMa, and includes the plurality of word lines WL. The stacked body LMc is arranged on the stacked body LMb, and includes the plurality of word lines WL and one or more selection gate lines SGD.

Note that, also in the second embodiment, similarly to the above-described first embodiment, the semiconductor memory device 2 may include a stacked body having a two-tier structure, or may include a stacked body having one-tier structure or a structure including four or more tiers.

In addition, in the semiconductor memory device 2 of the second embodiment, the memory region MR is formed similarly to the memory region MR in the above-described first embodiment.

As illustrated in FIG. 23, the step region SR2 included on one side in the Y direction divided by the plate-like contact LI in the semiconductor memory device 2, includes a step portion SP2 in which the plurality of contacts CC is arranged, and a dummy step portion SP2d arranged on one side in the Y direction of the step portion SP2, and is opened toward the plate-like contact LI on another side in the Y direction of the step portion SP2.

As described above, the step portion SP2 in which the plurality of contacts CC is arranged is on a side of the step region SR2 that is away in the X direction from the memory region MR neighboring in the X direction. Although not illustrated, the dummy step portion SP2d is further arranged on a side of the step region SR2 that is near in the X direction to the memory region MR, that is to say, on a side facing the step portion SP2.

These dummy step portions SP2d have a configuration in which the contact CC is not arranged, and a drawing function of the word line WL and the like is not included, and are formed more steeply than the step portion SP2 having the drawing function of the word line WL and the like.

Further, while the step portion SP2 has a continuous step shape from the stacked body LMa toward the stacked body LMc through the stacked body LMb, the step portion SP2d has an discontinuous step shape between the stacked bodies LMa to LMc. That is to say, for example, a step portion of the stacked body LMb is configured to overlap a step portion of the stacked body LMa in the stacking direction, and a step portion of the stacked body LMc is also configured to overlap these step portions in the stacking direction regarding the step portion SP2d.

By having such a configuration, it is possible to reduce an area occupied with these step portions SP2d being a dummy configuration in the semiconductor memory device 2.

Note that, in the step portion SP2d that faces the step portion SP2 in the X direction, and is close to the memory region MR, the contact CC connected to the selection gate line SGD is arranged in some cases.

The step region SR2 including the above-described step portions SP2 and SP2d is obtained by forming a mask pattern such as a photoresist layer that includes an opening, at the middle of the stacked body LM2 before replacement, for example, and repeating slimming and etching of the stacked body LM2 a plurality of times.

In the above-described processing, to maintain a layer thickness of the mask pattern at a certain layer thickness or more, a new mask pattern is formed again every predetermined number of times of slimming, and processing is continued. By adjusting an opening position of the mask pattern when forming the mask pattern a plurality of times, among four sides of the mortar shape, the step portion SP having a relatively gentle shape is formed on one side, and the steep and discontinuous step portions SP2d are formed on other sides.

After that, by dividing the above-described mortar-shaped portion by the slit ST, two sets of step portions SP2 can be obtained.

Similarly to the above-described first embodiment, also in such step regions SR2, columnar portions HR2m and columnar portions HR2s are arranged on a plurality of arrays extending in the direction along the X direction, and for each of these arrays, either of the columnar portions HRm and HRs is selected and arranged. Here, the layer structures of the columnar portions HR2m and HR2s are similarly to the respective layer structures of the columnar portions HRm and HRs in the above-described first embodiment, and these columnar portions HR2m and HR2s are different in that the columnar portions HR2m and HR2s extend with penetrating through the stacked body LM2 having the three-tier structure.

Further, similarly to the above-described first embodiment, among a plurality of arrays of the columnar portions HR2m and HR2s, the columnar portions HR2s are arranged on an array at least partially overlapping the array positions of the contacts CC in the X direction, and an array neighboring the array positions of the contacts CC or the plate-like contact LI in the Y direction.

Further, the columnar portions HR2m are arranged on the other arrays, that is to say, arrays that are away from the array positions of the contacts CC in the Y direction, and not neighboring the plate-like contact LI.

In the example in FIG. 23, in the step region SR2 at one side in the Y direction divided by the plate-like contact LI, the columnar portions HR2s and HR2m are arranged on seven arrays extending in the direction along the X direction. Among these arrays, the columnar portions HR2s are arranged on three arrays in total including arrays neighboring the contact CC at the Y direction both sides, and an array neighboring the plate-like contact LI in the Y direction, and the columnar portions HR2m are arranged on the other four arrays.

In addition, in the example in FIG. 23, an array neighboring the plate-like contact LI that divides the step region SR2 also neighbors the contact CC. However, a plurality of arrays may be arranged between the plate-like contact LI and the contact CC, and in this case, the columnar portions HR2s or the columnar portions HR2m are appropriately arranged on the plurality of arrays.

FIG. 24 illustrates an application example in which the columnar portions HR2m and HR2s are arranged in accordance with the above-described prescription in the configuration of the second embodiment.

FIG. 24 is a schematic diagram illustrating one of application examples in a case where the columnar portions HR2m and HR2s are arranged on the basis of the prescription in the semiconductor memory device 2 according to the second embodiment. More specifically, FIG. 24 is an XY cross-sectional view at the height position of the selection gate lines SGD, and includes a part of the memory region MR on one side of the stacked body LM2 in the X direction, and a part of the step region SR2.

As illustrated in FIG. 24, in each region of the step region SR2 divided by the plate-like contact LI in the Y direction, the plurality of separating layers SHE extending from the memory region MR reaches the step portion SP2d arranged closer to the memory region MR.

Further, in a portion in which the selection gate lines SGD of the above-described step portion SP2d are processed in a step-like shape, two contacts CC connected to each of the sections of the selection gate lines SGD are arranged. That is to say, in the example in FIG. 24, the stacked body LM2 includes two layers of the selection gate lines SGD.

Further, the plurality of contacts CC respectively connected to the plurality of word lines WL and the selection gate line SGS is arranged in the step portion SP2 that faces the above-described step portion SP2d in the X direction, and is arranged on a side away from the memory region MR in the X direction. These contacts CC are arranged in a region closer to the plate-like contact LI that divides the step region SR2, for example, on one array along the plate-like contact LI in the direction along the X direction. In addition, the contacts CC connected to the plurality of selection gate lines SGD may be arranged also in the step portion SP2.

Further, in the example illustrated in FIG. 24, both of a plurality of pillars PL and a plurality of columnar portions HR2m and HR2s have staggered arrangement. The number of arrays of the pillars PL arranged in the direction along the X direction, within one block region BLK is 24.

On the other hand, a diameter and a pitch of the columnar portions HR2m and HR2s are made larger than a diameter and a pitch of the pillars PL. Thus, within one block region BLK, the columnar portions HR2m and HR2s arranged in the direction along the X direction are arranged on 15 arrays.

In the step portion SP2 having the above-described configuration, in the portion in which the selection gate lines SGD is processed in a step-like shape, the columnar portions HR2m are arranged in a dispersed manner on a plurality of arrays over the entire one block region BLK including the vicinity of the contact CC and a position neighboring the plate-like contact LI.

Further, in a portion in which the word line WL and the selection gate line SGS of the step portion SP2 are processed in a step-like shape, the columnar portions HR2s are arranged in the vicinity of the contact CC and at positions neighboring the plate-like contact LI.

In the example in FIG. 24, the columnar portions HR2s are arranged, as arrays including points proximal to the contacts CC, on three arrays in total, including one array entirely overlapping in the X direction the array of the plurality of contacts CC arranged in the direction along the X direction, and two arrays neighboring the array positions of the contacts CC on the both sides in Y direction. Further, the columnar portions HR2s are arranged on arrays respectively neighboring two plate-like contacts LI sandwiching one block region BLK from both sides in the Y direction, as arrays neighboring the plate-like contacts LI.

On the other hand, the columnar portions HR2m are arranged on the remaining ten arrays. That is, the columnar portions HR2m are arranged on one array between the array of the columnar portions HR2s that neighbors the plate-like contact LI that divides the step region SR2 in the Y direction, and the array of the columnar portions HR2s that is on the plate-like contact LI side, among two arrays neighboring the contact CC in the Y direction. Further, the columnar portions HR2m are arranged also on nine arrays between the array of the columnar portions HR2s that neighbors the contact CC on the opposite side in the Y direction, and the array of the columnar portions HR2s that neighbors the plate-like contact LI on the other side.

According to the semiconductor memory device 2 of the second embodiment, the plurality of contacts CC is arranged in the step portion SP2 of the step region SR2 divided in the Y direction by the plate-like contact LI, at least on one line in the direction along the X direction. Further, a plurality of columnar portions HR2s and HR2m is arrayed on the plurality of arrays, and arranged on the above-described step portion SP2.

In this manner, also in the second embodiment, by appropriately arranging the columnar portions HR2s and HR2m, a stacked body in the replacement processing is supported more surely, and in subsequent processing, subduction of the stacked body LM2 can be prevented.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a stacked body including a plurality of conductive layers stacked apart from each other, the stacked body having a step portion where the plurality of conductive layers is processed in a step-like shape;
a plurality of contacts arranged in the step portion at least on one line in a first direction intersecting with a stacking direction of the stacked body, the plurality of contacts being respectively connected with the plurality of conductive layers;
a pillar extending in the stacking direction in the stacked body deviated from the step portion, the pillar forming a memory cell at a respective intersection with at least a part of the plurality of conductive layers; and
a plurality of columnar portions arranged in the step portion to form a plurality of arrays each extending in the first direction, the plurality of columnar portions extending in the stacking direction, wherein
the plurality of columnar portions includes:
a plurality of first columnar portions including a first insulating layer, the plurality of first columnar portions having a layer structure different from that of the pillar, and
a plurality of second columnar portions having a same layer structure as that of the pillar,
a first group including at least a part of the plurality of first columnar portions is arranged on an array at least partially overlapping an array position of the plurality of contacts in the first direction, among the plurality of arrays, and
a second group including at least a part of the plurality of second columnar portions is arranged on an array away from the array position of the plurality of contacts in a second direction intersecting with the stacking direction and the first direction, among the plurality of arrays.

2. The semiconductor memory device according to claim 1, wherein
at least another part of the plurality of first columnar portions is arranged on an array neighboring an array of the plurality of contacts in the second direction, among the plurality of arrays.

3. The semiconductor memory device according to claim 1, wherein
the first columnar portions of the first group are arranged on an array partially overlapping the array position of the plurality of contacts in the first direction, at a position shifted in the second direction from an array of the plurality of contacts.

4. The semiconductor memory device according to claim 1, further comprising:
a plate-like portion extending in the stacking direction and the first direction in the stacked body including the step portion, the plate-like portion dividing the stacked body in the second direction, wherein
at least another part of the plurality of first columnar portions is arranged on an array neighboring the plate-like portion in the second direction, among the plurality of arrays.

5. The semiconductor memory device according to claim 1, wherein
the step portion includes:
a first step portion that is arranged on one end in the first direction of the stacked body, the first step portion including a first region; and
a second step portion that is arranged on another end in the first direction of the stacked body, the second step portion including a second region facing the first region in the first direction,
the plurality of contacts is selectively arranged in the first region among the first and second regions, the first columnar portions of the first group are arranged on the array at least partially overlapping the array position of the plurality of contacts in the first direction in the first region, and
at least another part of the plurality of second columnar portions is arranged on an array at least partially overlapping the array position of the plurality of contacts in the first direction in the second region.

6. The semiconductor memory device according to claim 5, further comprising:
a plate-like portion extending in the stacking direction and the first direction in the stacked body, the plate-like portion dividing the stacked body in the second direction in the first and second regions, wherein
at least another part of the plurality of first columnar portions is arranged on an array neighboring the plate-like portion in the second direction, among the plurality of arrays, in the first and second regions.

7. The semiconductor memory device according to claim 1, further comprising:
first to third plate-like portions extending in the stacking direction and the first direction in the stacked body including the step portion, the first to third plate-like portions being arranged from one side to another side in the second direction with being apart from each other in the second direction, wherein
the step portion is arranged at least on one end in the first direction of the stacked body,
the plurality of contacts is selectively arranged on a first region of the step portion among the first region and a second region of the step portion, the first region being positioned between the first and second plate-like portions, the second region being positioned between the second and third plate-like portions,
the first columnar portions of the first group are arranged on the array at least partially overlapping the array position of the plurality of contacts in the first direction in the first region, and
at least another part of the plurality of second columnar portions is arranged on an array in the second region, which corresponds to the array in the first region in which the first columnar portions of the first group are arranged, among the plurality of arrays.

8. The semiconductor memory device according to claim 7, wherein
at least another part of the plurality of first columnar portions is arranged on an array neighboring the first to third plate-like portions in the second direction, among the plurality of arrays, in the first and second regions.

9. The semiconductor memory device according to claim 1, further comprising:
a plate-like portion extending in the stacking direction and the first direction in the stacked body including the step portion, the plate-like portion dividing the stacked body in the second direction, wherein
the step portion includes a first step portion and a second step portion that are arranged in a region between both ends in the first direction of the stacked body, the first and second step portions being divided in the second direction by the plate-like portion,
the plurality of contacts is arranged in each of the first and second step portions at least on one line in the first direction, and
the first and second columnar portions of the first and second groups form at least a part of the plurality of arrays in the first and second step portions, and are respectively arranged in the first and second step portions.

10. The semiconductor memory device according to claim 1, wherein
the plurality of first columnar portions includes the first insulating layer made of a substantially single material, and
the plurality of second columnar portions each includes:
a semiconductor layer that extends in the stacking direction,
a second insulating layer that covers a side wall of the semiconductor layer,
a third insulating layer that covers a side wall of the second insulating layer, and
a fourth insulating layer that is interposed between the second and third insulating layers, the fourth insulating layer including a material different from that of the second and third insulating layers.

11. A semiconductor memory device comprising:
a stacked body including a plurality of conductive layers stacked apart from each other, the stacked body having a step portion where the plurality of conductive layers is processed in a step-like shape;
a plurality of first contacts arranged in a partial region of the step portion at least on one line in a first direction intersecting with a stacking direction of the stacked body, the plurality of first contacts being respectively connected with the plurality of conductive layers;
a pillar extending in the stacking direction in the stacked body deviated from the step portion, the pillar forming a memory cell at a respective intersection with at least a part of the plurality of conductive layers;
a plurality of columnar portions arranged in the step portion to form a plurality of arrays each extending in the first direction, the plurality of columnar portions extending in the stacking direction; and
first and second plate-like portions extending in the stacking direction and the first direction in the stacked body including the step portion, the first and second plate-like portions being apart from each other in a second direction intersecting with the stacking direction and the first direction, the first and second plate-like portions dividing the stacked body in the second direction, wherein
the step portion includes:
a first step portion that is arranged on one end in the first direction of the stacked body, the first step portion including a first region between the first and second plate-like portions, and
a second step portion that is arranged on another end in the first direction of the stacked body, the second step portion including a second region between the first and second plate-like portions,
the plurality of first contacts is selectively arranged in the first region among the first and second regions facing each other in the first direction,
the plurality of columnar portions includes:
a plurality of first columnar portions including a first insulating layer, the plurality of first columnar portions having a layer structure different from that of the pillar, and
a plurality of second columnar portions having a same layer structure as that of the pillar,
in the second region, a first group including at least a part of the plurality of second columnar portions is arranged in a dispersed manner on first arrays among the plurality of arrays, and
in the first region, a second group including at least a part of the plurality of first columnar portions is arranged on at least one array proximal to an array position of the plurality of first contacts, among second arrays facing the first arrays in the first direction.

12. The semiconductor memory device according to claim 11, wherein
in the first region, the first columnar portions of the second group are arranged on an array at least partially overlapping the array position of the plurality of first contacts in the first direction, among the second arrays.

13. The semiconductor memory device according to claim 12, wherein
in the first region, the first columnar portions of the second group are further arranged on an array neighboring an array of the plurality of first contacts in the second direction, among the second arrays.

14. The semiconductor memory device according to claim 11, wherein
in the first and second regions, at least another part of the plurality of first columnar portions is arranged on arrays neighboring the first and second plate-like portions respectively in the second direction, among the plurality of arrays.

15. The semiconductor memory device according to claim 11, wherein
in the first region, the first columnar portions of the second group and a third group including at least another part of the plurality of second columnar portions are arranged for each array of the second arrays, in such a manner that the plurality of first columnar portions and the plurality of second columnar portions are mixed on the second arrays, and
the second columnar portions of the third group are arranged on an array away in the second direction from the array position of the plurality of first contacts, among the second arrays.

16. The semiconductor memory device according to claim 11, further comprising:
a third plate-like portion extending in the stacking direction and the first direction in the stacked body including the step portion, the third plate-like portion being apart from the second plate-like portion in the second direction on an opposite side to the first plate-like portion, the third plate-like portion further dividing the stacked body in the second direction; and
a plurality of second contacts arranged at least on one line in the first direction in a partial region of the step portion that is different from the region where the plurality of first contacts is arranged, the plurality of second contacts being respectively connected with the plurality of conductive layers, wherein
the first step portion includes a third region between the second and third plate-like portions,
the second step portion includes a fourth region between the second and third plate-like portions,
the plurality of second contacts is selectively arranged in the fourth region among the third and fourth regions facing each other in the first direction,
in the third region, at least another part of the plurality of second columnar portions is arranged in a dispersed manner on third arrays among the plurality of arrays, and
in the fourth region, a fourth group including at least another part of the plurality of first columnar portions is arranged in at least one array proximal to an array position of the plurality of second contacts among fourth arrays facing the third arrays in the first direction.

17. The semiconductor memory device according to claim 16, wherein
in the fourth region, the first columnar portions of the fourth group are arranged on an array at least partially overlapping the array position of the plurality of second contacts in the first direction, among the fourth arrays.

18. The semiconductor memory device according to claim 16, wherein
in the first to fourth regions, at least further other part of the plurality of first columnar portions is arranged on arrays neighboring the first to third plate-like portions respectively in the second direction, among the plurality of arrays.

19. The semiconductor memory device according to claim 16, wherein
in the fourth region, the first columnar portions of the fourth group and a fifth group including at least further other part of the plurality of second columnar portions are arranged for each array of the fourth arrays, in such a manner that the plurality of first columnar portions and the plurality of second columnar portions are mixed on the fourth arrays, and
the second columnar portions of the fifth group are arranged on an array away in the second direction from array positions of the plurality of second contacts, among the fourth arrays.

20. The semiconductor memory device according to claim 11, wherein
the plurality of first columnar portions includes the first insulating layer made of a substantially single material, and
the plurality of second columnar portions each includes:
a semiconductor layer that extends in the stacking direction,
a second insulating layer that covers a side wall of the semiconductor layer,
a third insulating layer that covers a side wall of the second insulating layer, and
a fourth insulating layer that is interposed between the second and third insulating layers, the fourth insulating layer including a material different from that of the second and third insulating layers.
